(19) United States
(12) Patent Application Publication
(10) Pub. No.: US 2018/0225891 A1
(43) Pub. Date: Aug. 9, 2018

(54) AUTOMATED VEHICLE DISCOVERY AFTER CONNECTING TO AN AUTOMOTIVE DIAGNOSTIC PORT

(71) Applicant: Automatic Labs, Inc., San Francisco, CA (US)

(72) Inventors: Nicholas Philip Lambourne, San Francisco, CA (US); Ian Andrew Adam Kozlovich, Oakland, CA (US); Glen Phillip McGillan, San Francisco, CA (US)

(21) Appl. No.: 15/706,364

(22) Filed: Sep. 15, 2017

Related U.S. Application Data
(63) Continuation-in-part of application No. 15/428,033, filed on Feb. 8, 2017.

(51) Int. Cl. G07C 5/00; G01R 31/00; G07C 5/08

(52) U.S. Cl. CPC G07C 5/008; G07C 2205/02; G07C 5/0808; G01R 31/007

(57) ABSTRACT

A system and method are provided for connecting a device to an automotive diagnostic port of a vehicle. The method includes the steps of sampling a signal on each pin of a plurality of pins of the automotive diagnostic port to generate a signal map corresponding with the automotive diagnostic port, selecting a configuration from a list of configurations for the automotive diagnostic port based on the signal map, establishing communication with the vehicle via the automotive diagnostic port based on the selected configuration. The method may be performed by a system that includes at least one of a device connected to the automotive diagnostic port of a vehicle, a mobile device, and/or a server.

### CROSS-REFERENCE TO RELATED APPLICATIONS

This application is a continuation-in-part of U.S. application Ser. No. 15/428,033 (Attorney Docket No. ALABP001) titled “Application-Specific Integrated Circuit Configured to Interface with Automotive Diagnostic Port,” filed Feb. 8, 2017, the entire contents of which is incorporated herein by reference.

### FIELD OF THE INVENTION

The present invention relates to signal processing, and more particularly to an automated analysis of signals interfaced with an automotive diagnostic port.

### BACKGROUND

Automotive diagnostic ports have been designed into a vehicle's electrical system since computers became common for running the engine and/or other electrical systems in vehicles. Examples of automotive diagnostic ports include General Motors' proprietary ALDL (Assembly Line Diagnostic Link), a California standard for OBD-I (On-Board Diagnostics), the Society of Automotive Engineers (SAE) J1962 specification for OBD-II for vehicles sold in the United States, the EOBD (European On-Board Diagnostics) for vehicles sold in the European Union, and the JOBD (Japanese On-Board Diagnostics) for vehicles sold in Japan. The automotive diagnostic ports enable a scan tool to be connected to the vehicle to retrieve diagnostic test codes (DTCs) from the electrical components in the vehicle coupled to the automotive diagnostic port. Other data, such as data relating to the emissions of the vehicle, may also be accessed via the automotive diagnostic ports.

Early-version automotive diagnostic ports were proprietary and each vehicle manufacturer designed dedicated scan tools to interface with that manufacturer's vehicle. Accordingly, manufacturers were free to connect each pin of the automotive diagnostic port connector to a variety of different voltages, signals, or communication buses. The variety of voltages and or signals that can be connected to a particular pin of the automotive diagnostic port makes it extremely difficult to design a single scan tool that is capable of interfacing with multiple vehicles from different manufacturers. Furthermore, even the newer standards such as OBD-II only specify the connections of a subset of pins on the automotive diagnostic port connector. The remaining pins are unspecified and can be utilized at the manufacturer's discretion.

Consequently, any tool designed to connect with the automotive diagnostic port of a wide range of vehicles could see a wide range of electrical interfaces (e.g., various voltages, termination, signaling protocols, and current flow) on any particular pin of the automotive diagnostic port connector. Conventional scan tools will typically be designed for a specific vehicle or set of vehicles (e.g., all vehicles for a particular manufacturer released after 1995, etc.). Some multi-vehicle scan tools, such as smog tools, require the use of various adapters to connect to a variety of different automotive diagnostic ports, and also require a user to manually program the tool with the specific vehicle type. In other words, a user is required to manually enter the year, make, and model of a vehicle so that the tool can be configured to be used with that vehicle. Designing tools specific to one particular subset of vehicles is inefficient, requiring a service department to purchase a number of tools corresponding to a number of different vehicles serviced by the service department. Similarly, multi-use tools that require manual configuration to be used with different automotive diagnostic ports are prone to error if the tool is misconfigured. Thus, there is a need for addressing this issue and/or other issues associated with the prior art.

### SUMMARY

A system and method are provided for connecting a device to an automotive diagnostic port of a vehicle. The method includes the steps of sampling a signal on each pin of a plurality of pins of the automotive diagnostic port to generate a signal map corresponding with the automotive diagnostic port, selecting a configuration from a list of configurations for the automotive diagnostic port based on the signal map, establishing communication with the vehicle via the automotive diagnostic port based on the selected configuration. The method may be performed by a system that includes at least one of a device connected to the automotive diagnostic port of a vehicle, a mobile device, and/or a server.

### BRIEF DESCRIPTION OF THE DRAWINGS

FIG. 1 illustrates an application-specific integrated circuit configured to interface with an automotive diagnostic port, in accordance with one embodiment;

FIG. 2 illustrates an automotive general purpose input/output, in accordance with one embodiment;

FIG. 3 illustrates the Input/Output Toolbox, in accordance with one embodiment;

FIG. 4 illustrates a package that includes the application-specific integrated circuit, in accordance with one embodiment;

FIG. 5A illustrates an OBD-II automotive diagnostic port connector, in accordance with the prior art;

FIG. 5B illustrates an early model BMW automotive diagnostic port connector 550, in accordance with the prior art;

FIG. 6 illustrates a system configured to be plugged in to an automotive diagnostic port, in accordance with one embodiment;

FIG. 7 illustrates a schematic for connecting the application-specific integrated circuitto an automatic diagnostic port connector, in accordance with one embodiment;

FIG. 8 illustrates a system that enables automatic vehicle discovery to be performed when a device is connected to an automotive diagnostic port of a vehicle, in accordance with one embodiment;

FIGS. 9A & 9B illustrate a flowchart of a method for executing an automatic vehicle discovery algorithm, in accordance with one embodiment;

FIGS. 10A, 10B, & 10C illustrate a flowchart of a method for determining a state of the vehicle, in accordance with one embodiment;

FIG. 10D illustrates a system for detecting an ignition check event, in accordance with one embodiment;

FIG. 11 illustrates a flowchart of a method for generating a fingerprint of a vehicle, in accordance with one embodiment;

FIG. 12 illustrates a flowchart of a method for executing the automatic vehicle discovery algorithm in a cold start mode, in accordance with one embodiment;

FIG. 13 illustrates a flowchart of a method for executing the automatic vehicle discovery algorithm in a hot start mode, in accordance with one embodiment; and

FIG. 14 illustrates an exemplary system in which the various architecture and/or functionality of the various previous embodiments may be implemented.

### DETAILED DESCRIPTION

Automotive diagnostic ports provide an interface to a variety of electrical systems for a vehicle. Examples of automotive diagnostic ports include, but are not limited to, OBD-I, OBD-II, EOBD, and JOBD. The OBD-II physical interface is specified as a 16-pin, D-style connector. The OBD-II interface includes one pin connected to a battery voltage (pin 16 is connected to a 12V or 24V source voltage) and two pins connected to ground (pin 4 is connected to chassis ground of the vehicle and pin 5 is connected to a signal ground). The OBD-II interface also reserves six pins for three specific communications interfaces. Pins 2 and 10 are connected to a positive line and a negative line of an SAE J1850 serial communications bus, respectively; pins 6 and 14 are connected to a high signal and a low signal of a CAN (Controller Area Network) bus, respectively; and pins 7 and 15 are connected to a K-line and L-line of a Keyword Protocol 2000 serial communications bus, respectively. The OBD-II interface reserves the last seven pins (i.e., pins 1, 3, 8, 9, 11, 12, and 13) for proprietary use by each manufacturer. In other words, a vehicle manufacturer may utilize these seven pins to communicate with various electrical components in the vehicle to retrieve additional diagnostic information. Other automotive diagnostic ports may map communications busses to different pins and/or connect different pins to varying voltage sources.

When connecting a device to the automotive diagnostic port, the device may be configured to automatically discover the mapping of pins to signals. In other words, the device may be configured to determine the voltages of the signals and the type of signals for each pin of the automotive diagnostic port. By analyzing the signals on each of the pins during various states of the vehicle, a device can be configured to automatically discover the communications protocols used on various pins and initiate communication with the vehicle's systems via those communication protocols.

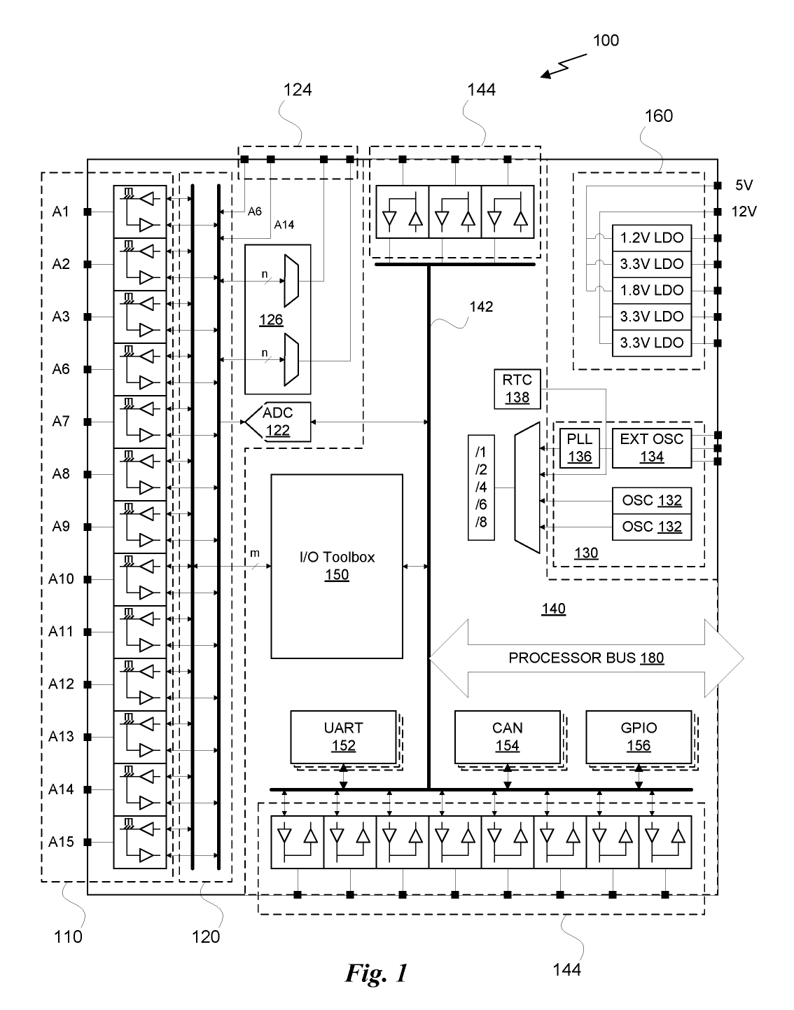

FIG. 1 illustrates an application-specific integrated circuit (ASIC) 100 configured to interface with an automotive diagnostic port, in accordance with one embodiment. The ASIC 100 is an integrated circuit formed in a silicon substrate. The ASIC 100 may include both an analog domain and a digital domain. The analog domain includes analog circuits comprising a number of components formed in the silicon substrate and configured to work with analog signals. The digital domain includes digital circuits comprising a number of components (e.g., CMOS logic) formed in the silicon substrate and configured to work with digital signals. Analog signals may be sampled by analog-to-digital converters (ADCs) to transition from the analog domain to the digital domain, and digital signals may be converted by digital-to-analog converters (DAC) to transition from the digital domain to the analog domain.

The ASIC 100 includes an input/output port 110 to interface with the automotive diagnostic port. The port 110 includes a number of pads, each pad designed to be coupled to a signal from one of the pins of the automotive diagnostic port. As shown in FIG. 1, in some embodiments, the port 110 includes 13 pads designed to be connected with the pins of an OBD-II diagnostic port, excluding the battery supply voltage and ground pins (i.e., pins 4, 5, and 16). Each pad is connected to an interconnect formed in the silicon substrate in order to route the signal at the pin to an I/O block designed to interface with a signal of an automotive diagnostic port, which may be referred to herein as automotive general purpose input/output (AGPIO).

It will be appreciated that 3 of the 16 pins of the OBD-II connector are reserved for the battery supply voltage and ground signals. The ASIC 100 may not need to interface with these pins directly, as the battery supply voltage and ground can be connected directly to a supply voltage for the ASIC 100. Therefore, in one embodiment, the ASIC 100 only includes 13 pads and 13 corresponding AGPIO in the I/O port 110. Of course, in various embodiments, the I/O port 110 may include a different number of pads and AGPIO in order to interface with one or more automotive diagnostic ports. For example, the I/O port 110 may include fewer pads and corresponding AGPIO to connect to only a subset of pins on the automotive diagnostic port. Alternatively, the I/O port 110 may include more pads and corresponding AGPIO to connect with a number of pins on a plurality of different automotive diagnostic ports. For example, the I/O port 110 may include a number of pads and corresponding AGPIO that matches the maximum number of pins in a plurality of different automotive diagnostic ports. Then, the same ASIC 100 can be utilized in a number of different applications, or with a number of different adapters to connect to more than one type of automotive diagnostic port.

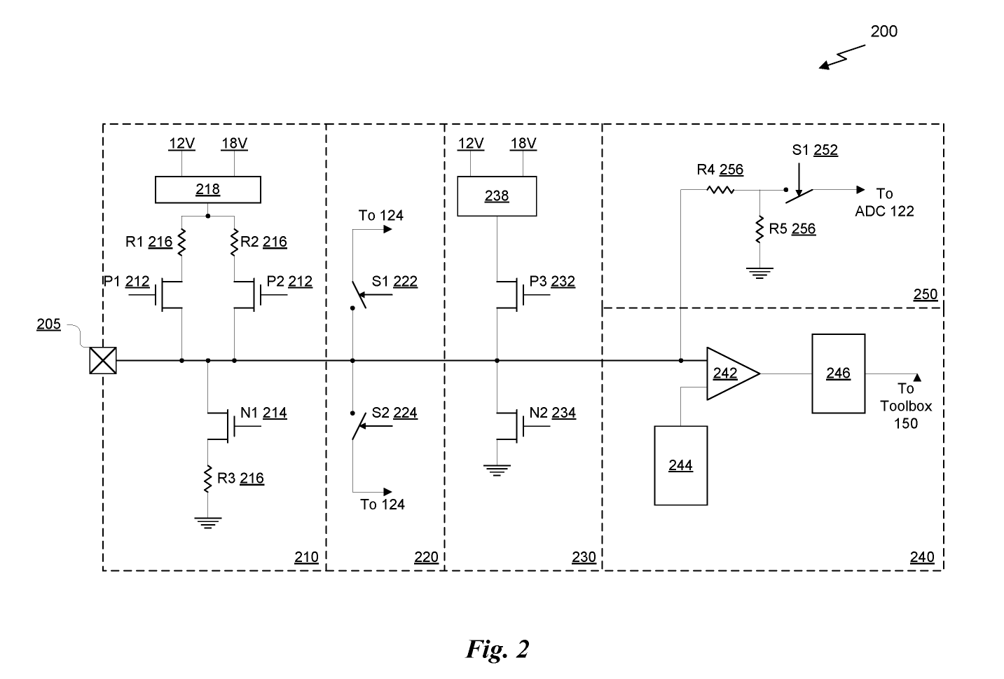

Each AGPIO is designed to operate when connected to a vehicle's electrical environment via the automotive diagnostic port connector. In one embodiment, the vehicle's electrical environment includes experiencing voltages applied to the input of the AGPIO ranging between −1 VDC and 40 VDC, operating in temperatures between −40° C. and 125° C., experiencing loss of ground protection, and normal operating voltages that may vary between different implementations of the automotive diagnostic port (e.g., 1.8 V, 3.3 V, 12 V, etc.). The vehicle's electrical environment is very different than a normal electrical environment of general purpose input/output (GPIO) implemented in conventional integrated circuits. For example, a normal GPIO may expect all signals connected to the GPIO pad to operate at a specific voltage (e.g., 3.3 V) and within a normal temperature range for processors in conventional packaging. Furthermore, the AGPIO may be expected to shunt large currents to a ground plane of the ASIC 100 without harming the integrated circuit that is out of the norm for conventional GPIO. The AGPIO will be described in more detail below in conjunction with FIG. 2.

Returning to FIG. 1, the AGPIO includes inputs and outputs coupled to a crossbar 120. In one embodiment, the crossbar 120 is configured with two ports: (1) a first port that can be configured to couple one or more outputs of the plurality of AGPIO to various components of the ASIC 100; and (2) a second port that can be configured to couple one or more components of the ASIC 100 to one or more inputs of the plurality of AGPIO. Each port may be reconfigured each clock cycle.

The crossbar 120 is connected to an ADC 122. The crossbar 120 may be configured to connect any of the signals from the I/O port 110 (e.g., A1-A3 and A6-A15) to an input of the ADC 122. In one embodiment, the ADC 122 is an 8-bit, 1 MHz, successive approximation data converter with an adjustable latency. Additional precision can be achieved by adjusting the full scale range of the ADC 122 to a subset of the default full scale range, set using a reference voltage generated with an internal bandgap of 0-3.3 VDC. The ADC 122 may be used to sample the analog signal received at a pad of the I/O port 110 and convert the signal to be processed in the digital domain 140 of the ASIC 100. The output of the ADC 122 may be coupled to a main system bus 142 in the digital domain 140 of the ASIC 100.

The ASIC 100 also includes an external CAN bus port 124 configured to connect pads of the I/O port 110 to a pair of external CAN bus transceivers. A first pair of pads in the external CAN bus port 124 may be connected to a first external CAN bus transceiver. In one embodiment, these pads are connected, via the crossbar 120, to the signals from pads A6 and A14 of the I/O port 110, which correspond with a high signal and a low signal of a CAN bus on the OBD-II automotive diagnostic port. A second pair of pads in the external CAN bus port 124 may be connected to an analog multiplexor 126. The analog multiplexor 126 enables a second external CAN bus transceiver to be coupled to any other pair of signals from the other pads of the I/O port 110 (e.g., pads A1-A3, A7-A13, and A15). One n-to-1 multiplexor in the analog multiplexor 126 connects a signal from a first pad of the I/O port 110 to the high signal (i.e., p line) for the second CAN bus transceiver, and another n-to-1 multiplexor in the analog multiplexor 126 connects a signal from a second pad of the I/O port 110 to the low signal (i.e., n line) for the second CAN bus transceiver.

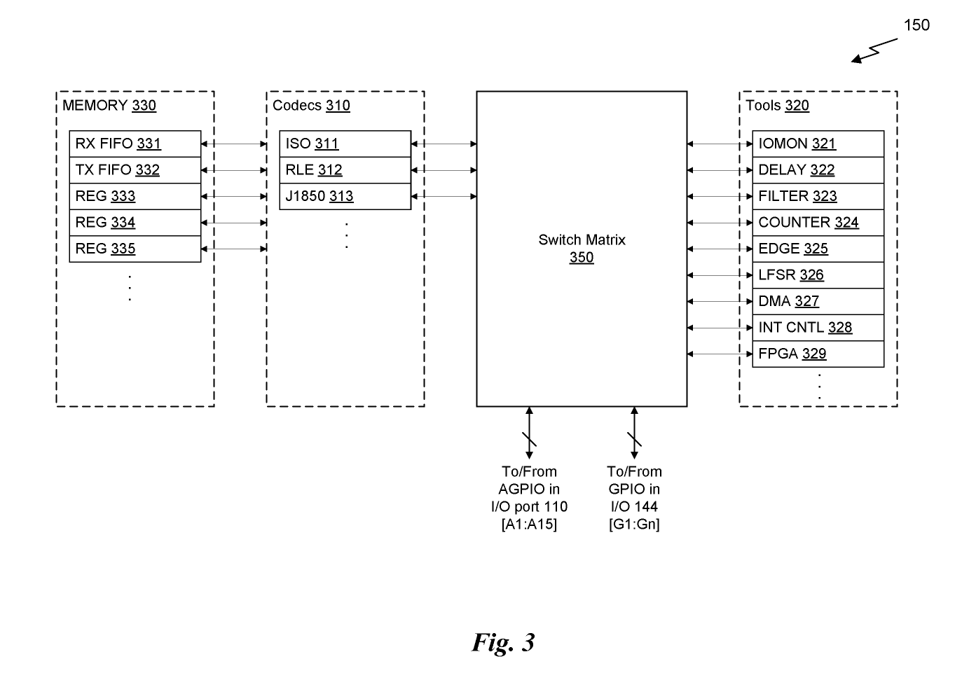

The crossbar 120 also connects m digital inputs from the I/O port 110 to the I/O Toolbox 150, which will be described in more detail below in conjunction with FIG. 3. The I/O Toolbox 150 is a collection of I/O protocol codecs for common automotive buses, a flexible set of modules for general purpose I/O, various signal processing tools such as filters, edge detectors, and delay modules, as well as buffers, registers, and a fully interconnected logical switching matrix to connect any source to one or more modules. Each module input can be connected to one source, and each module output can be connected to one or more destinations. The I/O Toolbox 150 enables the implementation of a flexible set of tools for performing general purpose I/O as well as signal processing without the real-time interaction of a CPU core.

The ASIC 100 includes a number of power generation components 160. In one embodiment, the ASIC 100 is coupled to a 12 VDC source supplied from a vehicle's supply voltage (e.g., a battery voltage) as well as a 5 VDC source supplied from an external voltage regulator. The ASIC 100 also includes a number of internal low-dropout voltage regulators (LDOs). The LDOs regulate either the 12 VDC source from the vehicle or the 5 VDC source from the external voltage regulator to supply various voltage domains with DC power at various levels. As shown in FIG. 1, the 5 VDC source is coupled to a 1.2 VDC LDO, a 3.3 VDC LDO, and a 1.8 VDC LDO. The 12 VDC source is coupled to a pair of 3.3 VDC LDOs. The LDOs may supply voltage domains to various components in the ASIC 100 as well as external components of the system coupled to one or more pads of the ASIC 100. It will be appreciated that, in other embodiments, other LDOs may be included in addition to or in lieu of the LDOs shown in FIG. 1. For example, additional 3.3 VDC LDOs may be included in the power generation components 160.

The ASIC 100 further includes a number of clock generation components 130. The clock generation components 130 include a number of RC oscillators 132 configured to generate a clock signal at various frequencies and an oscillator 134 that receives an oscillating signal from an external crystal oscillator and generates an external clock signal that matches the frequency of the external crystal oscillator. In one embodiment, a first RC oscillator 132 operates at 32.768 kHz, and a second RC oscillator 132 operates at 11 MHz, and the external crystal oscillator also must operate at 32.768 kHz. The external clock signal generated by the oscillator 134 is used to supply the input of a phase-locked loop (PLL) 136 that generates a system clock at 30 MHz. The external clock signal may also be output to supply a clock to the system connected to the ASIC 100. The clock signals from the clock generation components 130 are also tied to various components in the digital domain 140 of the ASIC 100.

In one embodiment, the external clock signal generated by oscillator 134 may be coupled to a real-time counter (RTC) 138. The 32.768 kHz signal increments a counter on each rising edge of the external clock signal. In one embodiment, the RTC 138 is a 44-bit counter. The value of the counter is a binary value representing an unsigned integer. The RTC 138 can be programmed to trigger an interrupt when the RTC 138 crosses a threshold value, as set in a special register. The RTC 138 may be reset when the interrupt is triggered in order to trigger interrupts at fixed intervals. The interrupts may be used to perform real-time operations. In one embodiment, the RTC 138 is only supplied by the external clock signal at a fixed frequency that matches the external crystal oscillator. The internal RC oscillator 132 at 32.768 kHz may not be accurate enough to ensure real-time operation due to process variations during fabrication and operating conditions such as fluctuating temperatures.

The clock signals from the RC oscillators 132, the external clock signal from the oscillator 134, and the system clock signal from the PLL 136 are tied to a multiplexor(s) that controls which clocks are enabled. In one embodiment, the external clock signal is routed to the RTC 138 via a multiplexor, which may enable or disable the RTC 138. The system clock may be selected from either the PLL 136 output at 30 MHz or the RC oscillator 132 output of 11 MHz. The output of the PLL 136 or the RC oscillator 132 is passed through a divider circuit that generates a system clock output of either 1×, ½×, ¼×, or ⅛× the frequency of the input to the divider circuit. Consequently, the system clock may be any of the following frequencies: 30 MHz, 15 MHz, 7.5 MHz, 3.75 Mhz, 11 Mhz, 5.5 MHz, 2.75 MHz, and 1.375 MHz. It will be appreciated that, in some embodiments, the frequencies of the oscillators and the available settings for the frequency of the system clock may be different than the frequencies described above.

The digital domain 140 of the ASIC 100 includes a number of I/O 144 coupled to the system bus 142 in order to provide digital I/O for the ASIC 100. The I/O 144 may include driving circuits to generate an output signal on each of the pads as well as level shifter logic to read an input signal on each of the pads. In one embodiment, all I/O 144 is configured to operate at 3.3 VDC logic levels, and can operate as tri-state outputs (i.e., logic high, logic low, and high impedence).

The digital domain 140 also includes a number of controllers for controlling the I/O 144. For example, the digital domain may include one or more UART (Universal Asynchronous Receiver/Transmitter) controllers 152, one or more CAN bus controllers 154, and one or more GPIO (General Purpose Input/Output) controllers 156. In one embodiment, the ASIC 100 includes four UART controllers 152, two CAN bus controllers 154, and one GPIO controller 156. Each UART controller 152 may be coupled to four pads included in I/O 144 tied to a transmit signal, a receive signal, an RTS (Request to Send) signal, and a CTS (Clear to Send) signal. Each CAN bus controller 154 may be coupled to three pads included in I/O 144 tied to a transmit signal, a receive signal, and a standby signal. Each GPIO controller 156 may be coupled to a number of pads included in I/O 144, the GPIO controller able to drive an output signal on each pad in the number of pads or read an input signal on each pad in the number of pads. For example, each GPIO controller may be able to control inputs and outputs for eight corresponding pads of the I/O 144.

Although not shown explicitly, the digital domain 140 may also include other controllers or components in addition to or in lieu of the controllers shown in FIG. 1. For example, the digital domain 140 may include a PWM (Pulse Width Modulation) controller for generating a PWM signal on one or more pads of the I/O 144. As another example, the digital domain 140 may include an I2C controller for communicating via the I2C communication protocol.

The ASIC 100 may also include a processor bus 180 configured to interface with a processor coupled to the ASIC 100. In one embodiment, the ASIC 100 is designed to be paired with an external CPU core on a second integrated circuit die that is flip-chipped with ASIC 100 to connect pads on one side of the ASIC 100 to pads on one side of the CPU core IC. The processor bus 180 enables fast communications between the digital domain 140 of the ASIC 100 and the CPU core coupled to the ASIC 100. Additional memory ICs (e.g., SDRAMs, Flash memory, etc.) may be connected to the CPU core IC to provide for volatile or non-volatile storage of data. The CPU core may be a RISC (Reduced Instruction Set Computer) processor such as an ARM® CPU core. In another embodiment, the digital domain 140 may include a CPU core that is coupled directed to the processor bus 180 within the integrated circuit of the ASIC 100. However, die size may be a limiting factor that precludes the CPU core from being included directly in ASIC 100.

FIG. 2 illustrates an automotive general purpose input/output 200, in accordance with one embodiment. An AGPIO 200 comprises a circuit implemented in a silicon substrate of the ASIC 100. The circuit is connected to a pad 205 of the I/O port 110, which is designed to be connected to a signal from one pin of the automotive diagnostic port. The circuit is divided into five sub-circuits: (1) a pull-up, pull-down (PUPD) sub-circuit 210; (2) a pass-thru CAN sub-circuit 220; (3) an output driver sub-circuit 230; (4) an input path sub-circuit 240; and (5) an ADC path sub-circuit 250. The signal from the pad 205 is routed to each of the five sub-circuits.

The PUPD sub-circuit 210 includes a pair of p-channel metal oxide semiconductor field effect transistors (MOSFETs) that implement pull-up functionality and a single n-channel MOSFET that implements pull-down functionality. A first p-channel MOSFET (pMOS) transistor (P1) 212 includes a drain connected to the signal from the pad 205, a source connected to a first resistor R1 216, and a gate connected to an enable signal to implement a strong pull-up functionality to a 12 VDC supply voltage. In one embodiment, the resistor R1 216 is a 510 Ohm polysilicon resistor which is connected, through a reverse current protection component 218 to a supply voltage of 12 VDC. A second pMOS transistor (P2) 212 includes a drain connected to the signal from the pad 205, a source connected to a second resistor R2 216, and a gate connected to an enable signal to implement a weak pull-up functionality to a 12 VDC supply voltage. In one embodiment, the resistor R2 216 is a 10 kOhm polysilicon resistor which is connected, through the reverse current protection component 218 to the supply voltage of 12 VDC. A first n-channel MOSFET (nMOS) transistor (N1) 214 includes a source connected to the signal from the pad 205, a drain connected to a third resistor R3 216, and a gate connected to an enable signal to implement a weak pull-down functionality to ground. In one embodiment, the resistor R3 216 is a 10 kOhm polysilicon resistor which is connected to ground.

In one embodiment, the reverse current protection component 218 may include a pair of pMOS transistors with a common node connected to the drain of both pMOS transistors and the 12 VDC supply voltage connected to the source of one pMOS transistor and the source of the other pMOS transistor coupled to the output of the reverse current protection component 218, which is then connected to the resistor R1 216 and the resistor R2 216. The gate of both pMOS transistors is then connected to a source of a third transistor, which may be, e.g., a bi-polar junction transistor, and a drain coupled to ground. When the third transistor is turned on, the pair of pMOS transistors are also turned on, enabling the 12 VDC current to flow through the reverse-biased channels of the pair of pMOS transistors. The gate of the third transistor may be tied to logic for detecting an overvoltage at the output of the reverse current protection component 218 (i.e., an overvoltage at the pad 205 caused by transient voltage spikes in the vehicles electrical system. In one embodiment, a comparator may compare the voltage at the output of the reverse current protection component 218 to a threshold voltage in order to determine when an overvoltage event has occurred and switch off the flow of current through the pair of pMOS transistors. The logic may utilize the 18 VDC supply as a threshold voltage that determines when to turn off the pair of pMOS transistor, or the threshold voltage may be set using a voltage divider to somewhere between the 12 VDC supply and the 18 VDC supply. In another embodiment, the reverse current protection component 218 is implemented with TVS diodes instead of MOSFETs.

The PUPD sub-circuit 210 enables the signal at the pad 205 to be pulled up to the 12 VDC supply voltage or pulled down to ground in order to prevent a floating input when the pad is connected to a high impedance external component. The strong pull-up function, weak pull-up function, and weak pull-down function can all be controlled individually by setting a bit in a special configuration register, which may be written by the CPU core in response to executing a series of instructions. It will be appreciated that the configuration of the PUPD sub-circuit 210 is exemplary, but that other pull-up or pull-down functionality may be implemented within the PUPD sub-circuit 210 by changing the resistance of each of the resistors, or adding more or removing each corresponding pair of MOSFET and resistor to match specific application requirements. For example, a strong pull-down functionality could be added to the PUPD sub-circuit 210 by including a second nMOS transistor coupled to a 510 Ohm resistor tied to ground.

The pass-thru CAN sub-circuit 210 includes analog switches that tie the signal at the pad 205 to the external CAN bus port 124. A first switch (S1) 222 connects the signal at the pad 205 to a high signal of the CAN bus port 124, and a second switch (S2) 224 connects the signal at the pad 205 to a low signal of the CAN bus port 124. In one embodiment, the switch S1 222 and the switch S2 224 are transistors, such as JFETs. A gate of the transistor is connected to an enable signal that turns on the transistor and passes the signal at the pad 205 to one of the four pads of the external CAN bus port 124, via the crossbar 120.

In one embodiment, the signal at pad 205 is connected to pads for the first external CAN bus transceiver if the pad 205 is tied to a particular pin of the automotive diagnostic port. For example, pads A6 and A14 of the I/O port 110, which are tied to pins A6 and A14 of the OBD-II port, are connected to a CAN bus of the vehicle and are routed to the first external CAN bus transceiver. The signal at pad 205 is connected to pads for the second external CAN bus transceiver, indirectly via the analog multiplexor 126, if the pad 205 is tied to any other pin of the automotive diagnostic port. In other words, the output of the pass-thru CAN sub-circuit 210 may be hardwired to one of the pair of pads in the external CAN bus port 124, where two of the pads of the I/O port 110 are hardwired to a first pair of pads in the external CAN bus port 124, and eleven of the pads of the I/O port 110 are hardwired to a second pair of pads in the external CAN bus port 124.

The output driver sub-circuit 230 enables the ASIC 100 to output a digital signal on the pad 205 using a configurable logic level. In one embodiment, the output driver sub-circuit 230 includes an nMOS transistor (N2) 234 that can be enabled to implement a strong drive logic low functionality. The output driver sub-circuit 230 may also include a pMOS transistor (P3) 232 that can be enabled to implement a strong drive logic high functionality. The transistor P3 232 may be coupled to a LDO voltage regulator 238 with reverse current protection. The LDO voltage regulator 238 is supplied with a 12 VDC supply voltage, which is used to generate one or more output voltages at one or more logic levels. In one embodiment, the LDO voltage regulator 238 is designed to generate a 5 VDC supply and an 8 VDC supply. The particular voltage level generated by the LDO voltage regulator 238 may be selected with a control signal and turned on in response to an enable signal. The reverse current protection in the LDO voltage regulator 238 may be implemented similar to the reverse current protection component 218, except coupled to the output of the LDO voltage regulator 238 instead of being coupled directly to the 12 VDC supply voltage. Furthermore, the 18 VDC supply may be used to generate the threshold voltage for triggering an overvoltage condition that restricts current flow.

In one embodiment, the transistor P3 and the LDO voltage regulator 238 may be omitted from the AGPIO 200 connected to some pads of the I/O port 110. Consequently, the AGPIO 200 connected to some pads of the I/O port 110 may include the functionality to drive the output strong high (e.g., 5V/8V/etc.) and strong low (e.g., ground), while the AGPIO 200 connected to other pads of the I/O port 110 may only include the functionality to drive the output strong low, relying on the pull-up functionality of the PUPD sub-circuit 210.

The input path sub-circuit 240 enables the ASIC 100 to output a digital signal on the pad 205 using a configurable logic level. In one embodiment, input path sub-circuit 240 includes a comparator 242, a threshold select unit 244, and level shifter logic 246. The threshold select unit 244 enables various logic levels to be utilized as a digital input at the pad 205. In one embodiment, the threshold select unit 244 includes the ability to select from three different logic levels: (1) 5 VDC, (2) 8 VDC, and (3) 12 VDC. The threshold select unit 244 generates a threshold voltage at approximately half of the full range voltage for a particular logic level. For example, the threshold select unit 244 generates a threshold voltage of approximately 6 VDC for a 12 VDC logic level (i.e., 12 VDC for logic high and 0 VDC for logic low), approximately 4 VDC for an 8 VDC logic level, and approximately 2.5 VDC for a 5 VDC logic level. The output of the threshold select unit 244 is connected to one input of the comparator 242, and the other input of the comparator is connected to the signal at the pad 205.

The comparator 242 generates an output at one of the rails of the supply of the comparator (e.g., 12 VDC). If the signal at the pad 205 is less than the threshold voltage generated by the threshold select unit 244, then the output of the comparator 242 is driven to the negative supply rail (e.g., 0 VDC). If the signal at the pad 205 is more than the threshold voltage generated by the threshold select unit 244, then the output of the comparator 242 is driven to the positive supply rail (e.g., 12 VDC). The output of the comparator 242 is connected to level shifter logic 246 to convert the logic level at the output of the comparator to a logic level compatible with the digital domain 140 (e.g., 3.3 VDC). The output of the level shifter logic 246 is connected to the I/O toolbox 150.

The ADC path sub-circuit 250 the ASIC 100 to measure an analog signal on the pad 205 using the ADC 122. The ADC path sub-circuit 250 connects the signal at the pad 205 to the ADC 122, via the crossbar 120, and is enabled by a switch (S3) 252. In one embodiment, the switch S3 252 is a transistor, such as a JFET, and a gate of the transistor is connected to an enable signal that turns on the transistor and passes the signal at the pad 205 to the ADC 122. The current flow to the ADC 122 is limited by a resistor R4 256, which may have a high resistance such as 1.4 MOhms. The amplitude of the signal provided to the ADC 122 is also not exactly the same as the amplitude of the signal at the pad 205, because the signal at the pad 205 is connected through a high impedance path to ground, via resistor R4 256 and resistor R5 256. The two resistors in series act as a voltage divider such that the amplitude of the signal transmitted to the ADC 122 is less than the amplitude of the signal at the pad 205. The gain of the voltage divider is set based on the ratio of resistance of the two resistors R4 256 and R5 256. In one embodiment, R5 256 has a resistance of 320 kOhms. The reason for reducing the amplitude of the signal transmitted to the ADC 122 is to reduce a full scale range of the ADC 122 to be less than the full scale range of the signal at the pad 205. Using a voltage divider in this fashion increases the signal to noise ratio (SNR) of the analog signal to get the benefit of a reduced complexity of the ADC 122.

FIG. 3 illustrates the I/O Toolbox 150, in accordance with one embodiment. As shown in FIG. 3, the I/O Toolbox 150 includes a number of I/O protocol codecs 310 for common automotive communications buses, a flexible set of tools 320, on-chip memory 330 including buffers and registers, and a fully interconnected logical switching matrix 350. The switching matrix 350 is configurable to connect various inputs to one or more codecs 310 and/or modules 320. In one embodiment, the inputs connected to the switching matrix 350 include the binary signal from the input path sub-circuit 240 of each AGPIO 200 coupled to a pad 205 of the I/O port 110. The I/O Toolbox 150 may include a digital front end that converts the binary signals from the input path sub-circuits 240 of each AGPIO 200 routed to the I/O Toolbox 150 to a digital signal sampled according to the system clock. The inputs connected to the switching matrix 350 may also include the digital signal of one or more GPIO coupled to a pad of the I/O 144.

In one embodiment, the I/O Toolbox 150 implements power-saving features. Each module (i.e., codecs 310, tools 320, and/or memory 330) may be subject to a hard reset condition that clears any state within the module and returns the module to a default state. In addition, each module may include circuitry for implementing clock gating. Clock gating prevents the system clock from being distributed to at least a portion of the module in order to prevent activity in the transistors of the module, which saves energy when the module is not in use.

The switch matrix 350 enables each of the modules in the I/O toolbox 150 to be interconnected. The term interconnected, within the context of the switch matrix 350 refers to the ability of the switch matrix 350 to be configured to couple an input node of a particular module (destination) to any source. As used herein, a source may be any one of the signals from the AGPIO included in I/O port 110 or the GPIO signals in I/O 144, as well as the output of any module. In one embodiment, each module includes a destination register that can be set to a value that indicates where the output of that module (source) should be routed in the switch matrix. The destination register can be written by software, executed in the CPU core, or by DMA request via a DMA controller in the digital domain 140.

In one embodiment, the input node of each module may only be connected to one source, but each module may specify zero or more destinations for the output. In another embodiment, the input node of each module may only be connected to one source and the destination register for the module may only specify zero or one destinations. In yet another embodiment, each module may include two or more input nodes, which may each be coupled to a different source. In one embodiment, the input node for a module may include a selectable inverter to invert the polarity of the source at the input node.

In one embodiment, the immediate state of each source signal coupled to the switch matrix 350 can be read by software by accessing special registers. In other words, the output of each module as well as the signals from the AGPIO and GPIO are stored in the registers, and updated by the modules coupled to the switch register (or updated as the signals on the pads of the AGPIO/GPIO are toggled externally. In another embodiment, a number of n-bit registers are used to store the previous n values of each source signal, with one register being associated with each source signal. The registers act as shift registers that store the state of the source signal for the previous n clock cycles.

The codecs 310 include blocks of digital logic to implement one or more I/O protocols. As shown in FIG. 3, the codecs 310 include, but are not limited to, an ISO controller 311, a run length encoder (RLE) controller 312, and a J1850 controller 313. It will be appreciated that other types of controllers may be implemented within the modules of codecs 310 to implement other communications protocols.

The ISO controller 311 is suitable for receiving or transmitting data encoded according to the ISO9141-2 or ISO14230 protocols. Under both protocols, the interpretation of data is dependent on the idle time of the communications bus immediately preceding each received symbol. The ISO controller 311 measures the idle time between symbols and stores a flag to indicate which symbols are the start of a frame or to indicate which symbols are the continuation of a frame. The timing of the inter-frame period and baud rate utilized by the ISO controller 311 are configurable in software, as executed by a CPU core. The baud rate is based on the system clock.

In one embodiment, the ISO controller 311 implements both a receiver and a transmitter. The ISO receiver module receives data symbols and stores data symbols in a RX FIFO 331 in the on-chip memory 330. The RX FIFO 331 can be accessed by software executed in the CPU core or by direct memory access (DMA) requests processed by a DMA controller in the digital domain 140. The ISO transmitter module transmits data symbols stored in a TX FIFO 332. In one embodiment, each byte stored in the TX FIFO 332 includes a flag in the most significant bit (MSB) that indicates whether the byte is the start of a frame of data. The ISO transmitter module, upon detecting the bit in a particular byte of the TX FIFO 332, will monitor the communications channel specified as the destination of the ISO controller 311 to wait for a bus idle condition. Once the bus has been idle longer than a programmable duration, the ISO controller 311 will transmit the data for the frame over the communications channel. It will be appreciated that although the ISO controller 311 is described as implementing both a transmitter and receiver in the same module of the codecs 310, separate and distinct modules for both the receiver and transmitter may be implemented within the codecs 310.

The RLE controller 312 enables the encoding or decoding of two RLE waveforms with a high-degree of timing precision, without any assistance from the CPU core. In one embodiment, the RLE controller 312 implements both a receiver and a transmitter. The RLE receiver module records a timestamp for each rising or falling edge of up to two waveforms. Each time at least one waveform has either a rising or falling edge, a timestamp is stored in a RX FIFO 331. The relative distance between successive timestamps indicates the number of bits at a particular state in the digital signal. The RLE transmitter module may generate up to two waveforms based on a particular state set in a first register and a number of clock cycles for encoding that state set in a second register. The value in the first register will be toggled when the number of clock cycles in the second register has expired, and the value in the second register will be updated based on a value popped from the TX FIFO 332. If the TX FIFO 332 is empty when the number of clock cycles in the second register has expired, then the output is set to zero. The J1850 controller 313 can send and receive J1850 frames utilizing Variable Pulse Width (VPW) and Pulse Width Modulation (PWM), in both differential and fault-tolerant, formats. In one embodiment, the J1850 controller is configured with timing parameters that can be individually controlled by software, executed in the CPU core. A register may be set to switch between the different modes of operation (i.e., VPW, PWMd, PWMft, etc.). The J1850 controller 313 utilizes a data register and a length register to load data for transmission on the communications channel. A start register may be used to start transmission of a frame of data. Each frame of data may be re-transmitted upon detection of an error or a loss of arbitration on the communications channel.

It will be appreciated that although only three exemplary modules are shown as being included in the codecs 310, in some embodiments, additional modules may be implemented within codecs 310 to control additional communications channels according to different protocols. In addition, multiple instances of the same modules may be included in the codecs 310 to control multiple communications channels in parallel.

The memory 330 includes on-chip memory that can be addressed by software executing in the CPU core (e.g., via DMA requests initiated on the processor bus 180 by the CPU core) and is accessible by the controllers of the various modules included in the codecs 310. As shown in FIG. 3, the memory 330 may include buffers such as RX FIFO 331 and TX FIFO 332 as well as a register file that includes a plurality of registers such as registers 333, 334, and 345. It will be appreciated that, in some embodiments, the memory 330 may include a different number of buffers or registers than shown in FIG. 3. For example, receive and transfer FIFOs for each module may be included in the memory rather than sharing FIFOs between multiple modules, or the number of registers may be changed in order to accommodate the requirements of different modules.

In addition to the codecs 310, the I/O Toolbox 150 also includes additional tools 320. The tools 320 include other modules that are not specifically related to encoding or decoding signals according to a specific communications protocol. In one embodiment, the tools 320 include an I/O Monitor module 321, a delay module 322, a filter module 323, a counter module 324, an edge detection module 325, a linear-feedback shift register (LFSR) module 326, a DMA module 327, an interrupt control module 328, and an FPGA (Field Programmable Gate Array) module 329.

The I/O Monitor module 321 is configured to monitor a signal to detect errors on a communications bus. The output of the I/O Monitor module 321 indicates whether an error has been detected. The I/O Monitor module 321 may also be configured to trigger an interrupt and/or disable AGPIO output in response to detecting an error on the communications bus.

The delay module 322 implements a digital delay line that propagates the input to the output after a programmable number of clock cycles.

The filter module 323 implements a filter on the signal. In one embodiment, the filter is an integrating filter that removes glitches (e.g., short pulses) on the input signal. The threshold for the length of a pulse that is filtered out may be configured by software executed in the CPU core.

The counter module 324 implements an event counter and may be configured to trigger an interrupt when the counter value passes a threshold. Examples of events include, but are not limited to, removing a glitch by the filter module 323, receiving a frame on a communications bus, detecting a rising or falling edge of a signal, detecting an error or loss of arbitration on a communication bus, and the like.

The edge detection module 325 can be configured to detect either a rising edge, a falling edge, or both a rising and falling edge in the input signal. Detection of an edge may trigger an interrupt, increment a counter, trigger a DMA request, or trigger data to be transmitted over a communications channel.

The LFSR module 326 implements a 16-bit LFSR that can be used to generate noise or may be used as a 1-bit random number generator. A probability of the output being a 1 or 0 can be controlled by software, and may have a number of pre-programmed settings. For example, the output signal may be programmed to have a ratio of logic 1 to logic 0 of 50%, 25%, 12.5%, 6.25%, 3.13%, 1.56%, and 0.78%. In other embodiments, the probability may be set using a register (e.g., an 8-bit value may specify a ratio of n/256, where n is the 8-bit value).

The DMA module 327 may be used to configure the behavior of four DMA channels utilized by the I/O Toolbox 150, and can be used to read or write to any of the buffers or registers in the memory 330.

The interrupt control module 328 controls interrupts. A number of different events can trigger interrupts within the I/O Toolbox 150 (e.g., edge detection, communications bus errors, a counter exceeding a threshold value, etc.) The interrupt control module 328 may be used to manage the interrupts, such as by capturing or masking each of the different types of events. The interrupt control module 328 may cause an interrupt request to be transmitted to the CPU core via the processor bus 180 in response to capturing an event, unless that event is masked.

The FPGA module 329 may be used to implement arbitrary digital logic. In one embodiment, the FPGA module 329 includes 16 configurable logic blocks, each containing one 4-input LUT and one flip-flop. The FPGA module 329 may also include, a number of counters, input buffers, output buffers, a routing matrix for connecting the configurable logic blocks, and a global clock network.

It will be appreciated that, in some embodiments, the number and type of modules included in the tools 320 may be different than the tools 320 described above. The tools 320 may include multiple instances of the same module, or may include other modules in addition to or in lieu of the modules shown in FIG. 3. For example, the tools 320 may include dummy modules that always output a 0 or a 1 in order to set the output state of the output driver sub-circuit of an AGPIO. Furthermore, although not shown explicitly, the tools 320 may be coupled to the memory 330 such that the modules in the tools 320 can access buffers or registers in the memory 330.

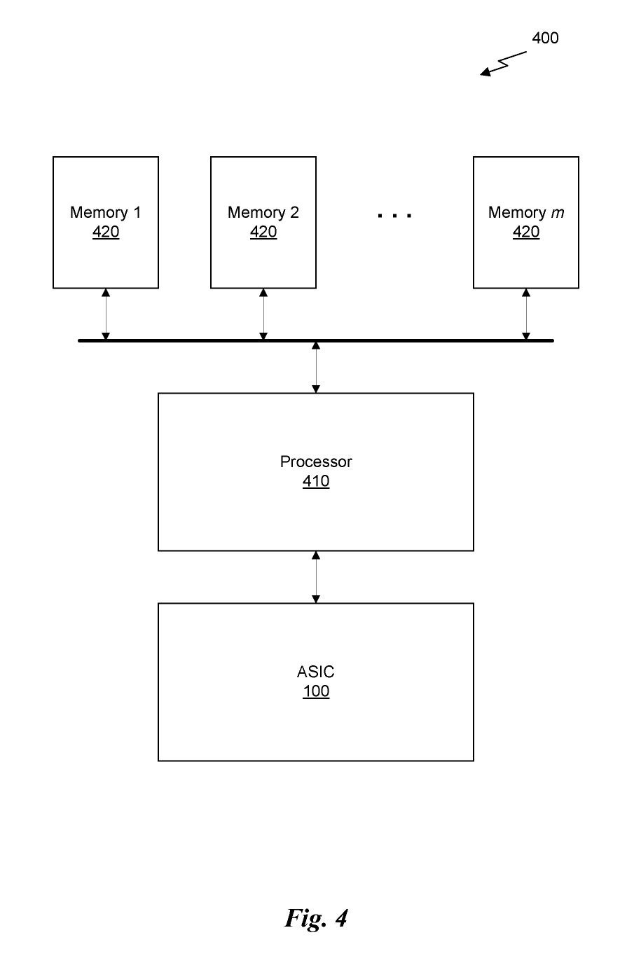

FIG. 4 illustrates a system 400 that includes the ASIC 100, in accordance with one embodiment. In one embodiment, the system 400 is contained in a package that includes one or more integrated circuit dies encapsulated in a resin or other material. The system 400 may include connections between the integrated circuit dies, such as with vias and printed circuits in a polymer substrate on which the dies are mounted or via metal paths such as solder bumps placed between pads on the dies in flip-chip technology or wires that have been bonded between pads on the dies in wire-bonding technology. The one or more dies are typically molded inside a resin material that completely encapsulates the one or more dies. Prior to molding, electrical connections may be made between at least some of the pads on at least one die and external leads such as pins or a ball grid array formed on a laminate substrate. In one embodiment, the system 400 is implemented as a QFN (Quad Flat No-leads) package with 72 external pins. In other embodiments, other packaging types may be utilized to stack the one or more dies. In yet other embodiments, package-on-package (PoP) technology may be employed to connect multiple packages containing subsets of the one or more dies in a single component.

As shown in FIG. 4, the system 400 includes the ASIC 100, a processor 410, and one or more memory modules 420. In one embodiment, the processor 410 may be a system-on-chip (SoC) that includes one or more CPU cores, one or more GPU cores, a memory management unit (MMU), a radio transceiver, a network interface controller (NIC), and the like. In another embodiment, the processor 410 may simply be a single CPU core. The single CPU core may be implemented on the same integrated circuit die as ASIC 100 or on a different integrated circuit die connected to ASIC 100.

In one embodiment, the processor 410 is a RISC-type microprocessor such as an ARM® Cortex CPU. The processor bus 180 of the ASIC 100 may be connected to a plurality of pads on the ASIC 100 that are coupled to a corresponding plurality of pads on an integrated circuit die of the processor 410. Consequently, the CPU core in the processor 410 may be able to communicate with the digital domain 140 of the ASIC 100. The CPU core of the processor 410 can then transmit DMA requests on the processor bus 180 in order to read or write data from on-chip memory in the ASIC 100.

The processor 410 may also include a memory interface coupled to a memory controller. In one embodiment, the memory 420 includes one or more SDRAM (Synchronous Dynamic Random Access Memory) modules coupled to a memory interface of the processor 410. The memory controller of the processor 410 is then configured to transmit read or write requests to the SDRAM modules to store volatile data. In another embodiment, the memory 420 includes one or more flash memory modules such as a NAND flash memory module. In yet another embodiment, the memory 420 is omitted from the system 400 and the processor 410 is coupled to the memory via an external memory interface.

In another embodiment, the ASIC 100, the processor 410, and the one or more memory modules 420 are implemented as separate packages. In such an embodiment, the system 400 may include a printed circuit board on which each of the separate packages is mounted and a plurality of traces to route signals between the various devices.

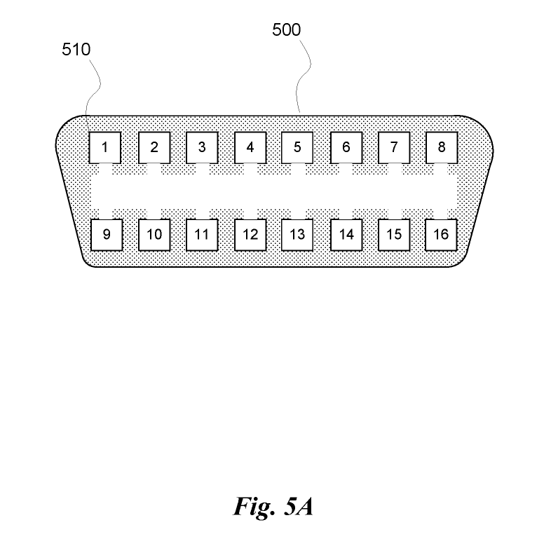

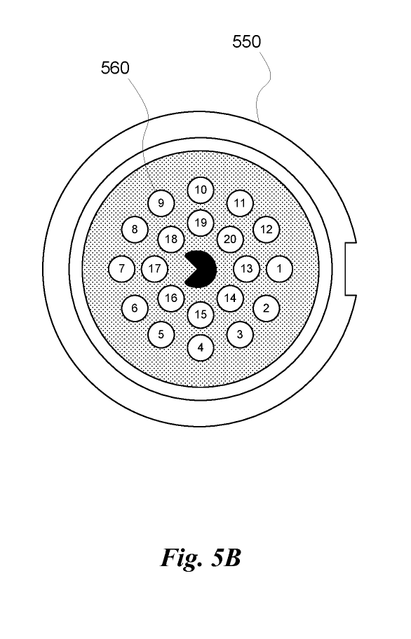

FIG. 5A illustrates an OBD-II automotive diagnostic port connector 500, in accordance with the prior art. The connector 500 for the OBD-II automotive diagnostic port was standardized as the SAE J1962 specification, which was issued in 1992. The United States has mandated inclusion of the OBD-II automotive diagnostic port connector 500 in any cars and light duty trucks sold in the U.S. market. The connector 500 is found within a specified distance of the steering column on all new cars/light duty trucks.

As shown in FIG. 5A, the OBD-II automotive diagnostic port connector 500, on a female connector, includes 16 sockets 510 arranged in two rows. A top row includes sockets 1 through 8, and a bottom row includes sockets 9-16. The sockets 510 accept 16 corresponding pins on a mating male connector. Sockets 2 and 10 are connected to a J1850 communications channel, sockets 6 and 14 are connected to a CAN communications channel, and sockets 7 and 15 are connected to an ISO 9141-2/14230-4 communications channel. Socket 4 is connected to a chassis ground of the vehicle, socket 5 is connected to a signal ground for the electrical system, and socket 16 is connected to a battery supply voltage of the vehicle. The remaining sockets 510 of the connector 500 are reserved to the manufacturers to implement additional diagnostic communications channels.

FIG. 5B illustrates an early model BMW automotive diagnostic port connector 550, in accordance with the prior art. Prior to various regulatory agencies mandating the use of a particular automotive diagnostic port connector, such as the OBD-II connector, in order to sell vehicles in a particular market, many manufacturers utilized a proprietary connector to interface with the diagnostic information provided by the vehicle. One such connector was the connector 550 shown in FIG. 5B. The female connector 550 included 20 sockets 560 configured to interface with 20 pins of a mating male connector. Socket 19 is connected to chassis ground, socket 14 is connected to a battery supply voltage of the vehicle, and the remaining sockets are connected to proprietary interfaces. For example, sockets 15 and 20 are connected to a receive data link and transmit data link to all control units, respectively. Socket 7 is connected to a service light reset, and socket 1 is connected to an engine speed signal.

Other manufacturers, at one time or another, have used various connectors in addition to the connectors shown in FIGS. 5A and 5B. For example, some Porsche vehicles utilized a 19-pin connector and some Mercedes Benz vehicles utilized a 14-pin connector. It will be appreciated that the ASIC 100 may include any number of AGPIO 200 within the I/O port 110 such that the ASIC 100 can communicate with any of these connectors utilizing a simple adapter to connect any socket of the vehicle's automotive diagnostic port connector to any one of the pads 205 of the I/O port 110.

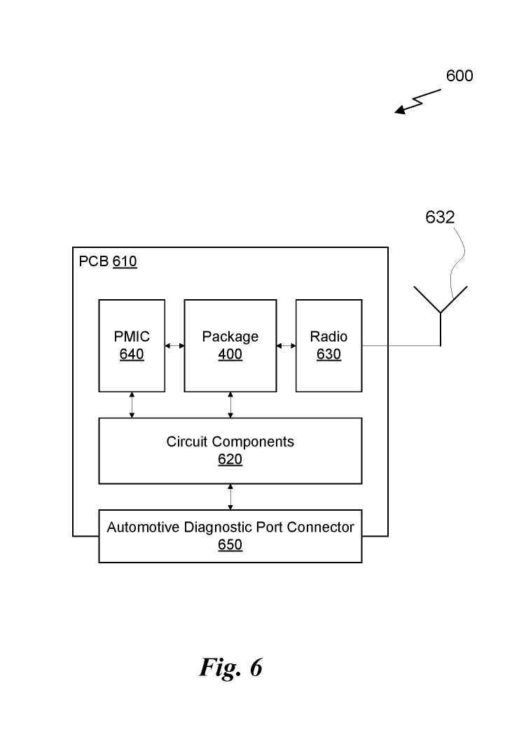

FIG. 6 illustrates a system 600 configured to be plugged in to an automotive diagnostic port, in accordance with one embodiment. The system 600 includes a printed circuit board (PCB) 610, on which a variety of electrical components have been mounted. In one embodiment, the PCB 610 is a multi-layer laminate with printed/etched metallic traces included therein on one or more layer to form various circuits and connect the electrical components.

As shown in FIG. 6, the system 600 includes the package 400, including ASIC 100, mounted thereon via a surface mount technique. The package 400 may be soldered to the board to connect the ASIC 100 to an automotive diagnostic port connector 650. In one embodiment, the automatic diagnostic port connector 650 is a male connector that includes a plurality of pins that fit into corresponding sockets of a mating, female diagnostic port connector included on a vehicle and connected to the vehicle's electrical system. The connector 650 may be D-type OBD-II connector, where the pins of the connector are soldered to a plurality of traces on the PCB 610.

The system 600 includes a power management integrated circuit (PMIC) 640 and a radio 630 coupled to the package 400. The radio 630 enables wireless communications through radio frequency (RF) channels. A wireless signal is transmitted to a receiver on another device via the antenna 632. In one embodiment, the radio 630 is used to implement Bluetooth® communication with another device, such as a cellular phone, a laptop, or another consumer device. In one embodiment, the Bluetooth communications channel can be used to communicate with the vehicle's audio system, in order to relay audio messages to a user.

The PMIC 640 is utilized to manage the power supplied to the package 400. In one embodiment, the system 600 receives power from the vehicle via the connector 650. For example, the connector 650 may couple pin 4 of an OBD-II connector to a ground plane of the PCB 610 and connect pin 16 to the PMIC 640, which includes a voltage regulator to generate a supply voltage (e.g., 12 VDC) for the package 400. The PMIC 640 may also include logic for placing the system 600 in a power saving mode. The power-saving mode may involve power-gating the package 400, thereby placing the ASIC 100 into a hard reset when the power is cycled. The ASIC 100 and/or the processor 410 may monitor various systems or signals to detect when to place the package 400 into a power saving mode. In one embodiment, the ASIC 100 and/or processor 410 may detect that the system 600 is idle, and place the ASIC 100 and/or processor 410 into a standby mode. The standby mode may include reducing a supply voltage of the package 400 and clock-gating various sub-systems in the package 400. In another embodiment, the ASIC 100 and/or processor 410 may monitor the system 600 to detect unsafe conditions like reverse polarity of the power supply or ESD discharge or overvoltage conditions and transmit a signal to the PMIC 640 to power gate the package 400 to prevent any damage to the package 400.

The signals from the automotive diagnostic port connector 650 may not be routed directly to the package 400 or PMIC 640. Instead, the signals may be conditioned or passed through one or more circuit components 620. In one embodiment, the circuit components 620 include a low-pass filter to smooth out the power supply from the vehicle. Vehicles can experience large voltage fluctuations due to the various components of the electrical system. For example, a starter motor, when the engine is being cranked, can draw a large amount of current, thereby dropping the voltage of the battery below 12 VDC. In addition, the alternator and distributor can generate a lot of noise in the vehicle's power supply. Consequently, the circuit components 620 may include capacitors and resistors sized to store energy and smooth out the power supply when experiencing short term voltage drops or spikes. In another embodiment, the circuit components 620 include current-limiting resistors placed in series between the pins of the connector 650 and the pads of the I/O port 110 of the ASIC 100. In one embodiment, each signal tied to an AGPIO of the I/O port 110 should include a 10 Ohm resistor in series with the pin on the connector 650 to limit the current drawn through the AGPIO circuit.

It will be appreciated that the system 600 is only one exemplary embodiment of an application for the ASIC 100. In other embodiments, the system 600 may include other components in addition to, or in lieu of, the components shown in FIG. 6. Such systems may take the form of, e.g., a laptop with a built-in automotive diagnostic connector to interface with a vehicle, a scan-tool used for diagnostic purposes, a data logger used to monitor the vehicle's electrical system and store diagnostic information in a solid-state drive, and many others.

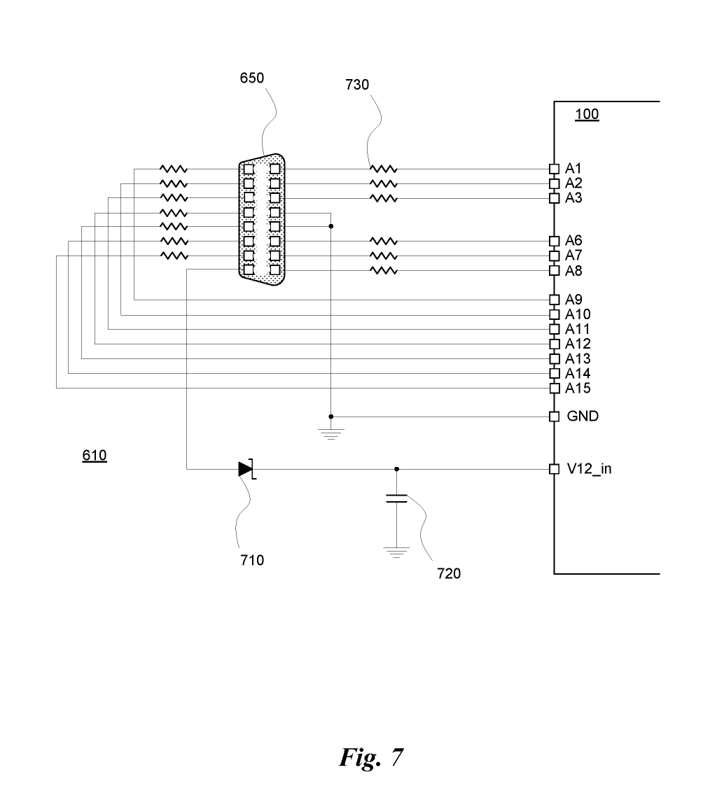

FIG. 7 illustrates a schematic for connecting the ASIC 100 to an automatic diagnostic port connector 650, in accordance with one embodiment. As shown in FIG. 7, the connector 650 is an OBD-II connector with 16 pins. Pins 4 and 5 are connected to a ground plane of the PCB 610. The ASIC 100 may also be coupled to the ground plane of the PCB 610. Pin 16 is connected to a V12_in pad of the ASIC 100, which supplies the ASIC 100 with a supply voltage. The 12 VDC power from the vehicle is connected, in series, with a Zener diode 710 before being connected to the V_12_in pad of the ASIC 100. The V_12_in pad is also connected to a capacitor 720. The other pins on the connector may be coupled to a pad 205 of an AGPIO (e.g., [A1-A3, A6-A15]), with a 10 Ohm, current-limiting resistor 730 between the pin and the pad 205.

### Vehicle Discovery

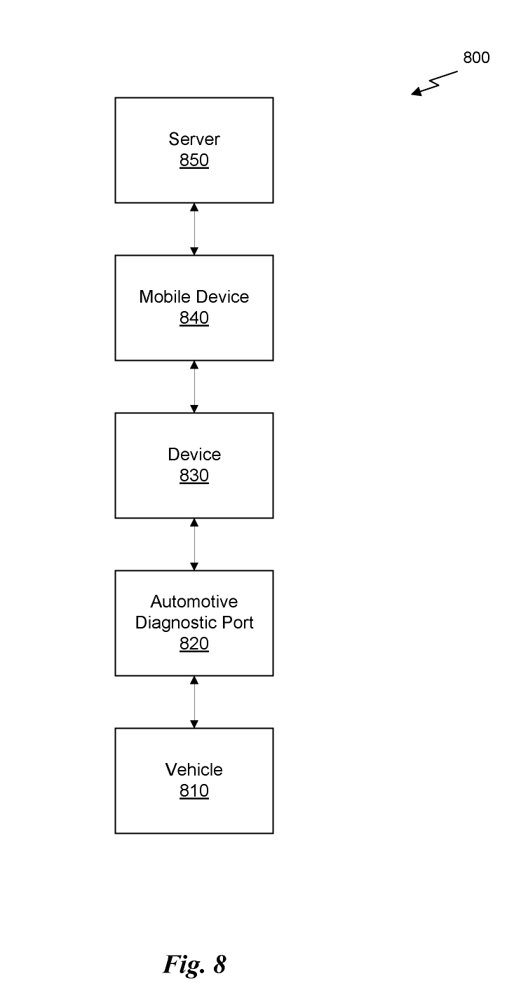

FIG. 8 illustrates a system 800 that enables automatic vehicle discovery to be performed when a device 830 is connected to an automotive diagnostic port 820 of a vehicle 810, in accordance with one embodiment. As shown in FIG. 8, a vehicle 810 includes an automotive diagnostic port 820. The vehicle 810 may have one or more vehicle systems connected to the automotive diagnostic port 820 via one or more communications channels or other signaling standards. For example, the vehicle 810 may implement a CAN bus for communicating with various electrical system components of the vehicle. The vehicle 810 may also have another communications bus for communicating with the engine control unit (ECU). The specific design for a vehicle's electrical system, and the communications protocols that components of that system use, varies from vehicle to vehicle. In various embodiments, the automotive diagnostic port 820 may conform to the OBD-II standard, the EOBD standard, the JOBD standard, the OBD standard, and the like.

A device 830 or tool may be connected to the automotive diagnostic port 820 of the vehicle such that the device can communicate with the various vehicle systems. In one embodiment, the device 830 may include the ASIC 100 connected to an automotive diagnostic port connector 650, as shown in FIG. 7. The ASIC 100 may be connected to the signals coupled to the pins of the automotive diagnostic port 820, via the automotive diagnostic port connector 650, such that the signals can be analyzed by the device 830, communications data can be received or transmitted on the communications busses implemented in the vehicle 810, and applications can be executed by the device that interact with the vehicle 810. It will be appreciated that the particular type of applications or functionality of the device 830 may vary depending on the intended operation of the device 830. The ASIC 100 may also be coupled to one or more additional components included in the device 830, such as memory modules, an SoC or RISC-type CPU, a wireless transmitter or radio, indicator LEDs, displays (e.g., LCDs), or other input/output type components such as buttons.

In one embodiment, the device 830 may be coupled to a mobile device 840. For example, the device 830 may be paired, wirelessly, with a mobile phone. The device 830 can be configured to connect with the mobile device 840 via various wireless protocols such as Bluetooth® when the mobile device 840 is proximate the vehicle 810 with the device 830 connected to the automotive diagnostic port 820. The mobile device 840 may include a processor and memory as well as additional components such as a touch-sensitive display, wireless radiofrequency transceiver, image sensor(s), speakers, and the like. The memory may include an operating system for the mobile device 840 as well as one or more applications. The processor is configured to execute the operating system to provide an operating environment for executing the one or more applications. In one embodiment, the mobile device 840 includes at least one application configured to communicate with the device 830 via a wireless communication channel established between the device 830 and the mobile device 840. In one embodiment, the device 830 does not include any input/output components and, therefore, relies on the input/output components of the mobile device 840 to prompt a user for information or display information to the user. The user may input information in response to the prompts using, e.g., a keypad, touch-sensitive display with virtual keyboard, microphone, image sensors or the like; and the user may receive output information via the display and/or speakers, for example.

In one embodiment, the mobile device 840 may also establish a communication channel with a server 850. For example, the server 850 may be accessed via the Internet using a TCP/IP protocol. The mobile device 840 may establish a connection to the Internet via a Wi-Fi® or cellular network that enables the applications on the mobile device 840 to communicate with the server 850. The applications may then transmit messages to the server requesting information from the server and receive messages from the server that include the information. The applications may also transmit data associated with the vehicle 810 to the server 850 as collected by the device 830 via the automotive diagnostic port 820 and transmitted to the mobile device 840 via the communication channel established between the device 830 and the mobile device 840.

In one embodiment, the server 850 is a front end for a service or services implemented by a plurality of nodes in one or more data centers. The server 850 may utilize a representational state transfer (RESTful) application programming interface (API) to transfer data between the server 850 and the mobile device 840. Upon receiving a hypertext transfer protocol (HTTP) request from an application on the mobile device 840, the server 850 may process the request. Processing the request may include the steps of executing a plurality of instructions on one or more nodes to process data included in the request, retrieve data from a database accessible by the plurality of nodes, processing the data from the database, generating data for display on the mobile device 840, transferring files to the mobile device 840, and the like.

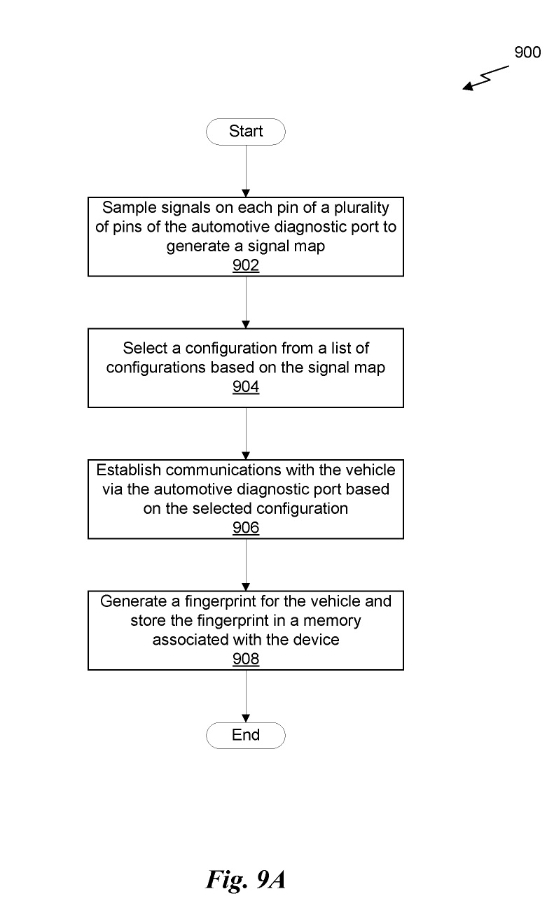

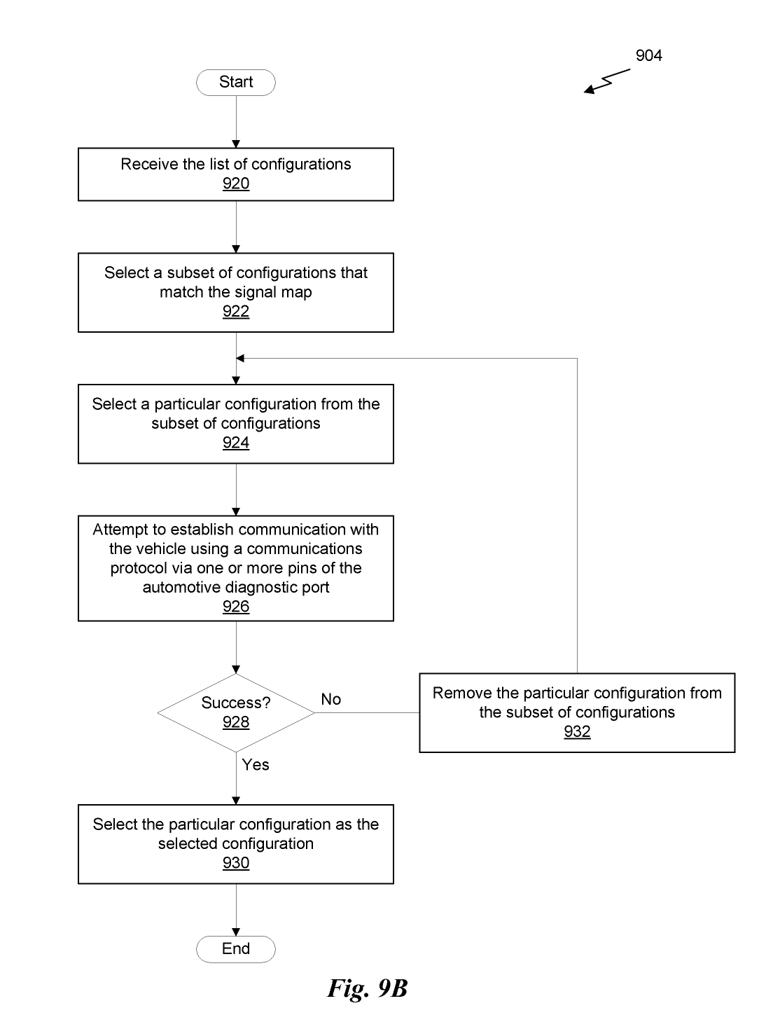

FIGS. 9A & 9B illustrate a flowchart of a method 900 for executing an automatic vehicle discovery algorithm, in accordance with one embodiment. The method 900 may be performed by hardware, software, or a combination of hardware and software. In one embodiment, the method 900 may be implemented by some combination of the device 830, the mobile device 840, and/or the server 850.

Prior to executing the automatic vehicle discovery algorithm, a device 830 is connected to an automotive diagnostic port 820 of a vehicle 810. In one embodiment, a user may be prompted, via a display included in the mobile device 840, to turn the vehicle 810 off (i.e., make sure the engine is not running) and plug the device 830 into the automotive diagnostic port 820. In many vehicles, the ignition system uses a key to turn a switch to one of a plurality of positions. The states of the ignition switch include: (1) OFF—where power to accessories and/or many auxiliary systems, such as the radio and the cabin heater, is disconnected; (2) ACC—where power to some accessories, such as the radio, is connected; (3) key-on, engine off (KOEO)—where power to the auxiliary systems is connected but the engine is not running; (4) key-on, engine-running (KOER)—where the engine is running and power is connected to vehicle systems; and (4) START—where the engine is started, usually by connecting power to a starter motor. For the purposes of this disclosure, an Ignition OFF state refers to any of the following states of the vehicle: (1) key removed and ignition switch in the OFF state; (2) ignition switch in the ACC state; (3) ignition switch in the KOEO state; and (4) ignition switch in the KOER state but the engine is not running. For the purposes of this disclosure, an Ignition ON state refers to any of the following states of the vehicle: (1) ignition switch in the KOER state and the engine is running; and (2) ignition switch in the KOER state but the vehicle is a hybrid vehicle with a running electric propulsion system. Once the device 830 has been plugged into the automotive diagnostic port 820, and is therefore connected to a power supply of the vehicle 810, the method 900 may be executed by the device 830.

At step 902, a signal is sampled on each pin of a plurality of pins of the automotive diagnostic port 820. In one embodiment, ASIC 100 is utilized to measure the voltage on each pin of a plurality of pins of the automotive diagnostic port 820. For example, each pin of the automotive diagnostic port 820 may be connected to an AGPIO 200 of an ASIC 100 included in the device 830. The signal from each pin may be routed to the ADC 122 via the ADC path sub-circuit 250 of the AGPIO 200, which converts the voltage level to a digital value that represents a level of the voltage relative to a reference voltage such as a ground potential. In one embodiment, the ASIC 100 is utilized to take a single sample of the voltage of each pin. In another embodiment, the ASIC 100 is utilized to take multiple samples of the voltage of each pin over a fixed time period to find an average voltage of each pin over the time period. In yet another embodiment, the ASIC 100 is utilized to take multiple samples of the voltage of each pin over the fixed time period, and the multiple samples are stored as a vector of voltage samples for the pin.

In one embodiment, the ASIC 100 is also utilized to measure an activity level on each of the pins of the automotive diagnostic port 820. Activity refers to the frequency of active switching of the signal between a logic low state and a logic high state. A high activity level would be expected if data was being transmitted over a bus, for example. In one embodiment, each pin of the automotive diagnostic port 820 may be connected to an AGPIO 200 and routed to toolbox 150 via the input path sub-circuit 240 of the AGPIO 200. The signal may be connected to the edge detection module 325 via the switch matrix 350, and the edge detection module 325 counts the number of rising or falling edges in the signal over a fixed time period. The number of edges counted in the time period may be stored as a representation of the level of activity of the signal on the pin.

In one embodiment, the sampled signals may be utilized to generate a signal map. The signal map correlates each of the sampled pins of the automotive diagnostic port 820 with measured voltages and/or activity level of each of the signals on the pins. The signal map may be stored in a memory associated with the device 830.

At step 904, a configuration is selected from a list of configurations based on the signal map. As used herein, a configuration for the automotive diagnostic port 820 refers to a mapping of signals or protocols to pins of the automotive diagnostic port 820. For example, a configuration for the automotive diagnostic port 820 where the automotive diagnostic port 820 conforms to the OBD-II standard, would map pins 4 and 5 to a ground potential, pin 16 to a battery supply voltage, pins 6 and 14 to a CAN bus, pins 2 and 10 to an SAE J1850 protocol, and pins 7 and 15 to an ISO 9141-2/ISO 14230-4 protocol. The configuration may list nominal values for a voltage and/or activity level of each of the signals for each of the pins of an automotive diagnostic port 820, as well as providing a tolerance for each of those values. For example, a nominal voltage may be given as 13 VDC plus or minus 2 V for a battery supply voltage signal. A nominal activity level may be given as a number of rising or falling edges within a fixed time period, such as 500 edges/ms plus or minus 200 edges. It will be appreciated that the activity level may have large tolerances as a number of rising and falling edges during transmission of data may depend on the underlying data and how many “1” and “0” values are transmitted over a serial communication link as well as a frequency of the carrier signal. Alternatively, the configuration may list a minimum and maximum value for the voltage or activity level of each signal, or simply a threshold level for the minimum voltage or activity level of a signal.

In one embodiment, the list of configurations is a list that includes all known configurations for various automotive diagnostic ports 820 implemented in vehicles 810 manufactured by a plurality of different manufacturers. In some embodiments, the list of configurations may be restricted to a subset of all known configurations by classification of vehicle (e.g., passenger car/truck, commercial vehicle, etc.) or by location (e.g., Europe, North America, etc.).

The signal map is used to select a particular configuration from the list of configurations that matches the measured signals on the pins of the automotive diagnostic port 820. By determining the voltage and/or activity level of each pin, certain configurations in the list of configurations can be excluded as not being compatible with the automotive diagnostic port 820. The configurations that match the signal map are potential configurations of the automotive diagnostic port 820 of the vehicle 810, and each potential configuration may be utilized to attempt to establish communications with the vehicle 810.

In one embodiment, the list of configurations for the automotive diagnostic port 820 is ordered according to a date that a particular configuration was first implemented in a vehicle. Establishing communication with the vehicle 810 may be attempted utilizing each potential configuration, as ordered in the list after discarding those configurations that do not match the signal map, one at a time. For example, GM implemented an Assembly Line Diagnostic Link (ALDL) protocol in 1980, the California Air Resources Board required all new vehicles sold in California to include on-board diagnostics (referred to as OBD-I) in 1991, the OBD-II specification was made a requirement for all new vehicles sold in the United States in 1996, the EOBD specification was made a requirement for all new vehicles sold in the European Union in 2001, and so forth. The ordered list of configurations for the automotive diagnostic port 820 may include an ALDL configuration, followed by an OBD-I configuration, followed by an OBD-II configuration, followed by the EOBD configuration, and so forth. This list is provided as merely one example of how a list of configurations is ordered and should not be construed as limiting.

In one embodiment, the device 830 attempts to establish communications with the vehicle 810 by transmitting a message over the automotive diagnostic port 820 on one or more pins of the automotive diagnostic port 820. The particular pins used to transmit the message may be selected according to the information included in the configuration. For example, the signal map(s) generated by the device 830 in step 902 may match a configuration that identifies pins 6 and 14 as implemented as a CAN bus. Consequently, the device 830 is configured to transmit the message over pins 6 and 14 using the communication protocol established for the CAN bus.

The device 830 may attempt to send a message for each configuration in the list of configurations that match the signal map, one at a time, in an order determined according to a date that a particular configuration was first implemented in a vehicle, starting with the oldest implemented configuration first and working up to the newest implemented configuration in the list of configurations. If an attempt fails, then the next configuration in the list of configurations that matches the signal map is selected and the message is resent according to that configuration (i.e., different pins of the automotive diagnostic port may be used, different protocols used, etc.).

In one embodiment, transmitting a message over the automotive diagnostic port 820 is performed by transmitting a Parameter ID code (PID) over a CAN bus of the vehicle 810 in order to request a vehicle identification number (VIN) corresponding to the vehicle 810. In some older vehicles, the PID may be transmitted to the vehicle using a different protocol other than the CAN bus (e.g., VPW or PWM via SAE J1850, ISO 9141-2, etc.), and the particular pin(s) to use to transmit the message, and the particular communications protocol associated with those pin(s), may be defined in the configuration. For example, mode 0h09 (given in hex) and PID code 0h02 may be used in a PID query to request a 17-character VIN using an OBD-II compliant automotive diagnostic port 820.

The attempt to communicate with the vehicle 810 fails when the device 830 does not receive a response from the vehicle 810 within a timeout period. In the event of a failure, the current configuration is discarded and a new configuration is selected from the list of configurations. Then, an attempt to establish communication with the vehicle 810 via the automotive diagnostic port 820 on the pin(s) and via the communications protocol indicated by the new configuration is performed. In some embodiments, one or more retry attempts may be performed before a particular configuration is discarded and a new configuration is selected from the list of configurations.

If all attempts to communicate with the vehicle 810 have failed and the list of configurations is empty, then a message indicating a failure has occurred may be displayed to a user via the mobile device 840. In such an event, the user may restart the automatic vehicle discovery algorithm, making sure that the vehicle 810 is in the Ignition OFF state. It will be appreciated that such errors may occur if the user failed to put the vehicle into the correct state (e.g., the vehicle was in the Ignition ON state when the vehicle should have been in the Ignition OFF state) prior to connecting the device 830 or if certain electrical systems of the vehicle are malfunctioning.

However, if communication with the vehicle 810 is successful, as indicated by receiving a valid response from the vehicle 810, then the configuration used to attempt to communicate with the vehicle 810 is selected as the selected configuration of the automotive diagnostic port 820 of the vehicle 810.

At step 906, communications with the vehicle 810 is established via the automotive diagnostic port 820 based on the selected configuration. In one embodiment, the VIN may be used to retrieve vehicle-specific configuration information from the server 850 that is more detailed than the information included in the configuration selected from the list of configurations in step 904. The VIN, as received in the valid response from the vehicle 810, may be sent to the server 850 via the mobile device 840 in order to retrieve information that matches the vehicle 810 from the server 850. Vehicle-specific data can be decoded from the VIN, which is composed of three sections: (1) a world manufacturer identifier; (2) a vehicle descriptor; and (3) a vehicle identifier. The world manufacturer identifier indicates the nation of origin, the manufacturer, and, possibly, the type of vehicle (e.g., passenger car, commercial truck, etc.). The vehicle descriptor indicates things such as the model, body type, restraint systems, and transmission and engine type. The vehicle identifier section indicates the model year, the assembly plant, and the serial number of the vehicle. The vehicle-specific data can be used to retrieve vehicle-specific configuration information that identifies all protocols implemented on the automotive diagnostic port 820 for the vehicle 810.

For example, a configuration in the list of configurations may conform to the known configuration of an OBD-II port for a large number of vehicles that share basic mapping of pins to a CAN bus via the OBD-II port. However, each vehicle that includes an OBD-II diagnostic port may map the reserved pins to different proprietary systems or communications protocols. Only one configuration in the list of configurations is needed generally to communicate with all of the vehicles with OBD-II diagnostic ports and retrieve the VIN for the vehicle 810 via the CAN bus. However, once the VIN for the vehicle 810 is known, the VIN can be used to query a database from the server 850 that retrieves the exact pin mapping of the automotive diagnostic port 820 for the vehicle 810 such that all communications protocols implemented by that vehicle 810 through the automotive diagnostic port 820 are known and can be utilized by the device 830. There is no need to add a separate and distinct configuration for each and every manufactured vehicle with an OBD-II connector to the list of configurations when attempting to communicate with an unknown vehicle at step 906.

At step 908, the device 830 may be configured to generate a fingerprint for the vehicle 810 and store the fingerprint in a memory associated with the device. As discussed in more detail below, a fingerprint is generated based on vehicle-specific information that can be accessed via the automotive diagnostic port 820 of the vehicle 810. The fingerprint can be used to check whether the device 830 is still connected to the same vehicle in the future when the device 830 is activated (i.e., turned on or brought out of a standby mode). The fingerprint may be utilized to speed up the vehicle discovery algorithm under certain conditions, as described in more detail below. After step 908, method 900 terminates.

In one embodiment, in the event that all attempts to communicate with the vehicle failed at step 904, then a user may be prompted to enter the VIN manually using the mobile device 840. For example, the user could locate the VIN on the vehicle and enter it using a keyboard associated with the mobile device 840, or the user could take a picture of the VIN as located on the vehicle (e.g., on the engine block, under the windshield on the dashboard on the driver's side of the vehicle, on the door frame of the vehicle, etc.) or on a document such as a registration for the vehicle and then image analysis can be used to locate and convert the image to find the VIN. The VIN can then be used to query the server 850 for a configuration corresponding to the vehicle 810, and the returned configuration can be used to attempt to communicate with the vehicle 810. It will be appreciated that requiring user input to enter the VIN is not desired if automated vehicle discovery can be performed without user input, so this method of detecting the configuration of the automotive diagnostic port 820 should only be used as a way to correct from an error condition when the automatic technique highlighted above fails for some reason, usually due to some type of malfunction (e.g., unusually low or high battery voltage conditions, corrupt ECU, etc.).

In one embodiment, a signal map matches a configuration when the voltage and or activity level sampled on a particular pin matches the values stored for that pin in the configuration. For example, a configuration may indicate that pin 16 should have a nominal voltage within a range defined between 11 VDC and 15 VDC. If the measured voltage of pin 16 of the automotive diagnostic port 820 is within this voltage range, then the signal map matches the configuration. In some embodiments, a signal map matches a configuration when the voltage and or activity level sampled on two or more pins matches the values stored for those pins in the configuration, and the two or more pins may be a subset of pins included in the automotive diagnostic port 820.

In one embodiment, the signals of the automotive diagnostic port 820 are sampled while the vehicle 820 is in two or more distinct states. Creating a signal map when the vehicle 810 is in the Ignition OFF state is important because the activity of the signals is generally at a minimum because some vehicle systems will not be activated and, therefore, these systems are not generating traffic on the various busses connected to the pins of the automotive diagnostic port 820. However, by sampling the signals when vehicle 810 is in the Ignition OFF state and again when the vehicle 810 is in the Ignition ON state, the number of matching configurations in the list of configurations can potentially be reduced.

In some embodiments, only a subset of values in the signal map may be required to match the configuration in order for the configuration to match the signal map. For example, only a pair of pins identified in a configuration as a ground and battery supply voltage may be checked against the measured voltage levels of the signals on those pins in order to determine if the configuration matches the signal map. Activity level of various pins connected to a communication bus may not be checked for the purposes of paring the list of configurations down to a subset of potential configurations of the automotive diagnostic port 820. It will be appreciated that measuring the voltage level of the battery, and determining which pin the battery voltage is connected to in the automotive diagnostic port 820, may be enough to significantly reduce the list of configurations of the automotive diagnostic port 820. This may also avoid possible errors where the correct configuration is discarded because the activity level of a communications bus at the time the signals were measured was outside of a normal activity level due to, e.g., unusual data patterns or missing or malfunctioning systems coupled to the communications bus.

In one embodiment, as shown in FIG. 9B, the step 904 can be further described as a series of sub-steps. At sub-step 920, the list of configurations for the automotive diagnostic port 820 is received. In one embodiment, the list of configurations may be retrieved from a server 850 and stored temporarily on the mobile device 840. The device 830 may then retrieve the configurations from the memory associated with the mobile device 840. In another embodiment, the device 830 may communicate directly with the server 850 via, e.g., a cellular frequency radio. At sub-step 922, a subset of configurations that match the signal map is selected from the list of configurations.

At sub-step 924, a particular configuration is selected from the subset of configurations. In one embodiment, each of the configurations in the subset of configurations will be selected, one at a time, in order to try to communicate with the vehicle 810. At sub-step 926, the device 830 attempts to establish communication with the vehicle 810 using a communications protocol via one or more pins of the automotive diagnostic port 820. The particular configuration identifies the one or more pins of the automotive diagnostic port 820 that implement the communications protocol. At sub-step 928, the device 830 determines whether communication was established. If the attempt to establish communication is successful, then, at sub-step 930, the particular configuration is selected as the selected configuration from the list of configurations and the method 900 proceeds to step 906. However, if the attempt to establish communication fails, then, at sub-step 932, the particular configuration is removed from the subset of configurations and the method 900 returns to sub-step 924 where a new configuration is selected from the subset of configurations as the particular configuration.

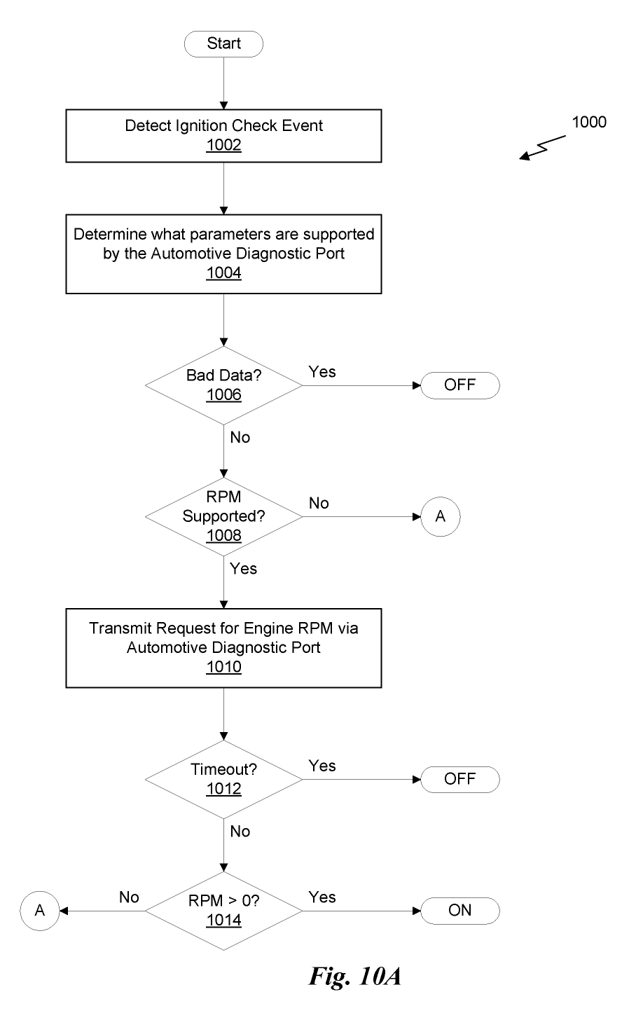

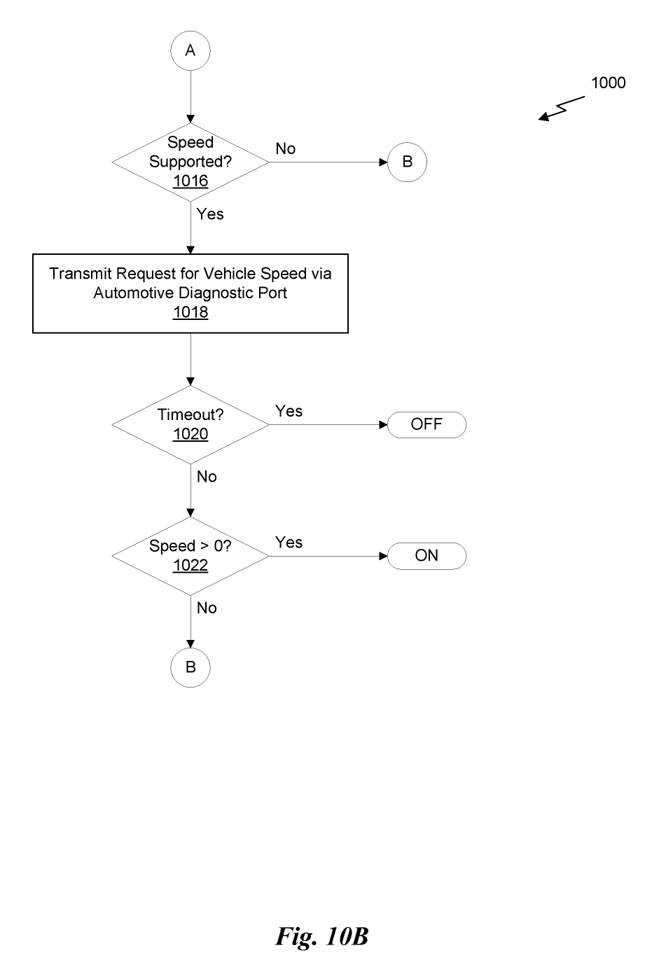

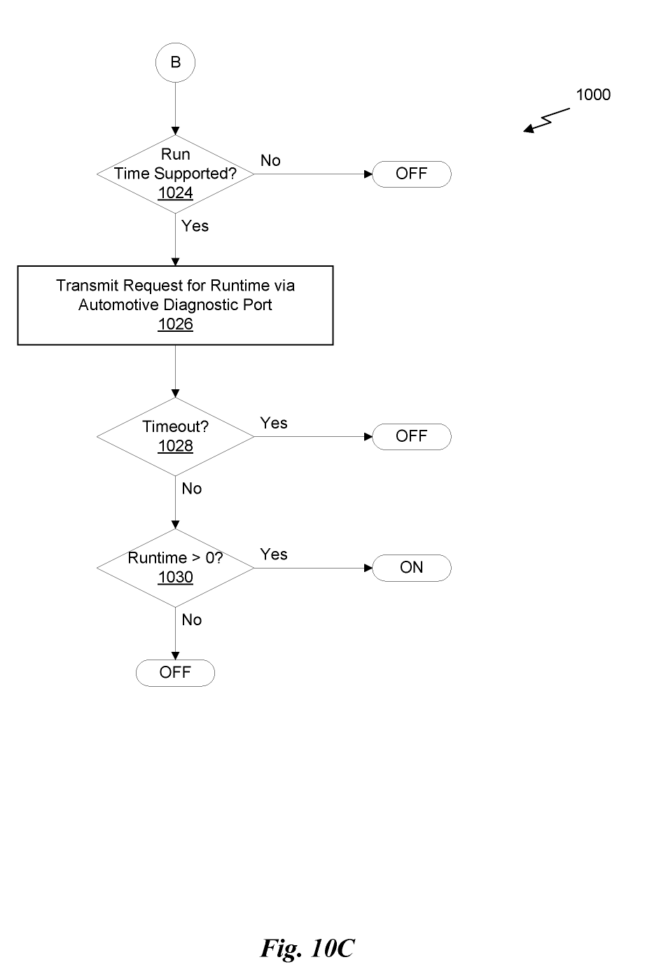

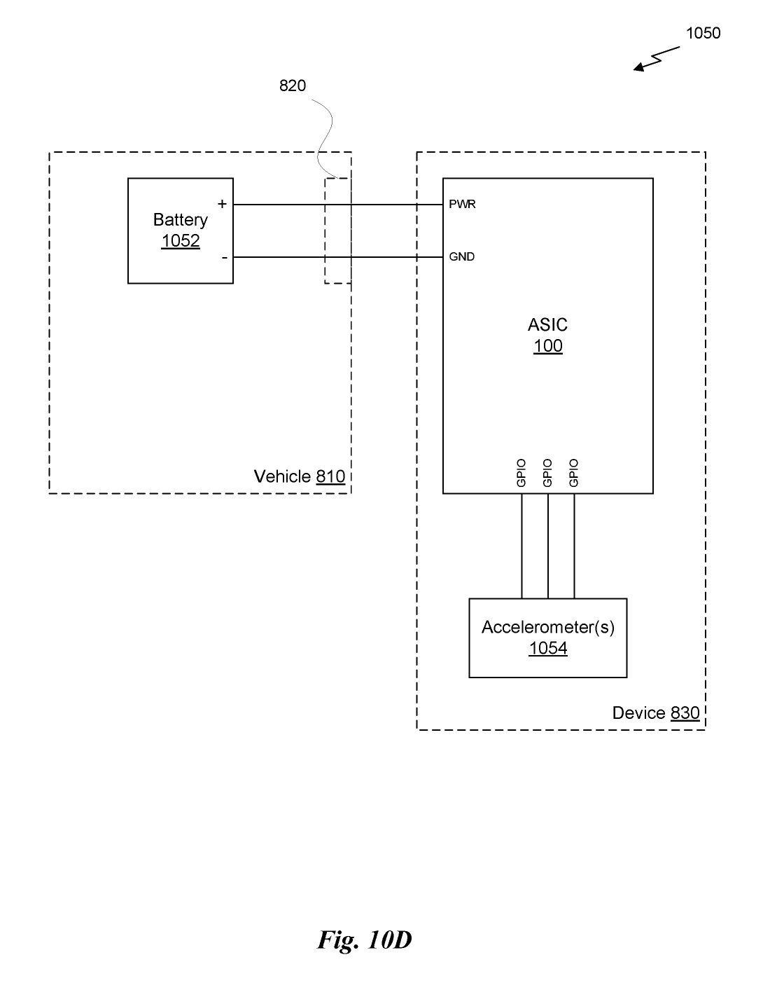

FIGS. 10A, 10B, & 10C illustrate a flowchart of a method 1000 for determining a state of the vehicle 810, in accordance with one embodiment. It will be appreciated that, once a device 830 is connected to a vehicle 810, there may be various applications that need to perform some operations when the vehicle is in a particular state. Conventionally, any diagnostic tool coupled to a vehicle relies on a prompt being displayed to a user to put the vehicle in a particular state and then indicate that the vehicle is in the state through some manual input such as by using a keypad. In one embodiment, it would be beneficial for the device to automatically detect the state of the vehicle 810. Detection of this sort would enable the device 830 to be placed in a low-power standby mode when the vehicle is OFF, and then automatically transition from the standby mode to a normal operating mode when the vehicle is ON.

At step 1002, a device 830 detects an ignition check event. In one embodiment, the device 830 is placed in a standby mode and monitors one or more signals or sensors while in standby mode. Even when the vehicle 810 is in an OFF state, the device 830 is still receiving power through the automotive diagnostic port 820. Signals may be connected to logic within the device 830 that generates an ignition check event signal when one or more conditions are satisfied. An ignition check event may be detected when any one of the following conditions occurs: (1) a voltage level of the battery exhibits a waveform that indicates a starter motor was connected to the battery to start the engine; (2) one or more accelerometers indicate the vehicle is in motion; or (3) activity on a communications bus indicates the vehicle is in motion. The logic generating the signal that indicates that an ignition check event has occurred may combine conditions using Boolean logic such as AND or OR. For example, in one embodiment, the logic may indicate an ignition check event has occurred when accelerometer data AND the battery voltage indicate that the vehicle is in motion. Furthermore, other conditions in addition to or in lieu of the conditions mentioned herein are within the scope of the present disclosure. For example, the device 830 may include a microphone that monitors for engine noise or the device may be coupled to a vehicle mounted camera that detects motion via image analysis of a plurality of frames of video.

In one embodiment, the device 830 monitors the battery voltage as one condition that could trigger an ignition check event. Most vehicles rely on an electric starter motor coupled to the battery through a starter solenoid in order to crank the engine and get the engine running. Starter motors are high current devices and, while lead-acid batteries and the like typically used in vehicles are designed to provide a large amount of current for short periods of time, drawing high current from the battery will typically result in a voltage drop across the terminals of the battery. For example, a fully charged battery may nominally have 12.6 VDC across the terminals. However, during cranking, the starter motor may draw somewhere between 60 and 200 Amps, which results in a significant voltage drop of a couple of volts. The actual voltage drop will depend on a variety of factors such as the type of battery, the current charge state of the battery, whether the electrical system includes large capacitors or other electric devices that can discharge during periods of unusually high current draw, the external temperature that changes the resistance of the engine to turn over, and so forth. Typically, the amount of voltage drop may be on the order of 2-3 VDC during cranking.

In addition, the waveform of the battery voltage may appear periodic during cranking. As a reciprocating piston engine is turned over, the resistance of the engine varies over a full rotation of the crank shaft. The engine resists the motion as gas is compressed in each cylinder. Consequently, the current drawn by the starter motor will increase as the resistance of the engine to turn over increases. Thus, the voltage at the battery will exhibit a waveform that roughly follows the resistance of the engine to turn over as the engine is cranked.

The device 830 may be configured to monitor the battery voltage, detect a voltage drop below a threshold amount, and/or look for a periodic frequency in the voltage waveform. In one embodiment, the device 830 samples the battery voltage on the pins of the automotive diagnostic port 820 at a particular sampling frequency (e.g., 100 Hz) using the ADC 122 of the ASIC 100. A number of samples may be accumulated to form a moving average of the battery voltage in order to filter the signal. If a difference between the battery voltage at a first sampling time and the battery voltage at a second sampling time is greater than a threshold value, then the device 830 may trigger the collection of a battery voltage waveform. The waveform can be collected by sampling the battery voltage on the pins of the automotive diagnostic port 820 at a different sampling frequency (e.g., 1000 Hz). The waveform samples over a sampling period (e.g., 1 s) may be stored in a memory and then analyzed using a discrete fourier transform to determine whether a signal at a frequency substantially matching a cranking frequency of the engine is above a threshold level. For example, a stable battery voltage would have a DC signal but very low or zero signals at other frequencies over the sampling period. However, a battery voltage experiencing periodic voltage drop while the starter motor is pulling varying amounts of current will have a signal at a particular frequency that substantially matches the RPM (rotations per minute) of the crankshaft multiplied by the number of cylinders that are in a compression stroke per 360 degree rotation (e.g., 4×RPM in a four-stroke, eight-cylinder engine).

It will be appreciated that the technique described above is not 100% reliable for detecting engine cranking. For example, battery voltage conditioners can significantly affect the voltage drop seen on the pins of the automotive diagnostic port. In addition, the cranking rpm and thus the expected frequency of the periodic signal may vary depending on various conditions such as the initial battery voltage or level of charge, viscosity of the oil used in the engine, the compression ratio of each cylinder, number of cylinders, and so forth. Consequently, a range of frequencies close to a DC frequency may need to be monitored when analyzing the voltage waveform. It may be possible that the device 830 could miss the condition that triggers an ignition check event in various situations. Therefore, it is not ideal to only rely on the battery voltage for detecting when a vehicle 810 is started.

In another embodiment, the device 830 may include sensors to detect one or more conditions. For example, circuit components 620 may include multi-axis accelerometers mounted to the PCB 610. The accelerometers may generate signals that are coupled to the ASIC 100 via GPIO 144. If the vehicle 810 is stationary, then the automotive diagnostic port 820 will also be stationary, and the device 830 connected to the automotive diagnostic port 820 should be stationary as well. Therefore, any signal generated by the accelerometers while the device 830 is coupled to the automotive diagnostic port 820 would indicate that the vehicle 810 is in motion. Vehicle motion is highly correlated to the engine running and, therefore, may indicate that the vehicle 810 is in the ON state.

In yet another embodiment, the device 830 may monitor a communication bus on the automotive diagnostic port 820. The activity on the communication bus may correlate with the state of the vehicle. For example, the communication bus may have very little activity on the bus while the ignition switch of the vehicle is in an OFF state, may have moderate levels of activity when the ignition switch of the vehicle is in an ACC or KOEO state, and may have the most activity when the ignition switch of the vehicle is in an KOER or START state. Consequently, monitoring the level of activity of a communication bus at a low frequency, counting the number of transitions per sampling period can give an indication that the vehicle 810 may be running and/or in motion as vehicle systems transmit more traffic over the bus.

As the aforementioned makes clear, the ignition check event may be detected, at least in part, using passive monitoring of the automotive diagnostic port 820. In other words, the device 830 monitors the signals on the pins of the automotive diagnostic port 820, but the device 830 does not actively transmit messages over any of the buses of the automotive diagnostic port 820 to try to communicate with the vehicle 810. The ignition check event, therefore, acts as an indicator that the device 830 should transition out of standby mode and attempt to actively communicate with the vehicle 810 via the communication busses of the automotive diagnostic port 820.

At step 1004, the device 830 transmits a request over the automotive diagnostic port 820 to retrieve a list of parameters supported by the automotive diagnostic port. In one embodiment, the device 830 transmits a PID request over the CAN bus of an OBD-II automotive diagnostic port 820. A PID request may be broadcast over the CAN bus using a specific broadcast identifier, and the PID request payload includes a size of the request, a mode, and a PID code, each of which is one byte wide. A PID response to the request may be broadcast over the CAN bus by the ECU or another controller in the vehicle, and the PID response includes a size of the response, a custom mode, a PID code, and a value of the specified parameter (up to four bytes). The specific PID request for the list of parameters supported by the automotive diagnostic port is standardized in SAE J/1979 as mode 0h01 (given in hexadecimal format), PID 0h00. The particular PID code returns a 4-byte bitmap that indicates whether the next 32 PID codes are supported by one or more vehicle systems, from MSB to LSB.

At step 1006, the device 830 monitors the automotive diagnostic port 820 for a response to the request. In one embodiment, the device 830 listens for a PID response on the CAN bus that includes a custom mode and PID code that correspond with the mode and PID code of the PID request. The custom mode is 0h40 added to the mode encoded in the request (e.g., 0h41 for mode 0h01), and the PID code in the PID response is the same as the PID code encoded in the PID request. If the device 830 does not receive a valid response to the request, then the method 1000 terminates with a determination that the vehicle 810 is in the OFF state. However, if the device 830 receives a response to the request, then the method 1000 proceeds to step 1008.

In one embodiment, at step 1006, the device 830 may set a timeout counter when the request is sent to track a time that the device 830 has waited for a response. A timeout period (e.g., 3 seconds) may be set such that the method 1000 terminates if no message is received by the time the timeout counter exceeds the timeout period.

At step 1008, the device 830 determines whether an engine RPM parameter is supported by the automotive diagnostic port 820. In one embodiment, the device 830 analyzes the PID response to PID code 0h00 received over the CAN bus. The specific PID code for engine RPM is standardized in SAE J/1979 as 0h0C. Consequently, the LSB of the high nibble of the 2^{nd} most significant byte of the 4 byte parameter value returned in the PID response to PID code 0h00 indicates whether PID code 0h0C is supported by the automotive diagnostic port 820. If the engine RPM parameter is not supported, then the method 1000 proceeds to step 1016, as shown in FIG. 10B. However, if the engine RPM parameter is supported by the automotive diagnostic port 820, then the method 1000 proceeds to step 1010.

At step 1010, the device 830 transmits a request over the automotive diagnostic port 820 to retrieve a parameter value for the engine RPM. In one embodiment, the device 830 transmits a PID request (mode 0h01, PID code 0h0C) over the CAN bus of an OBD-II automotive diagnostic port 820.

At step 1012, the device 830 monitors the automotive diagnostic port 820 for a response to the request to retrieve the parameter value for the engine RPM. In one embodiment, the device 830 listens for a PID response on the CAN bus that includes a custom mode and PID code that correspond with PID code 0h0C. A PID response to a PID request for PID code 0h0C returns a two byte value for the parameter that represents the RPM of the engine in ¼ RPM increments, between 0 and 16,383.75 RPM. In one embodiment, the device 830 may monitor the bus traffic for a particular period of time as set by a timeout period. When the timeout period expires without receiving a response to the request, the method 1000 terminates with a determination that the vehicle 810 is in an OFF state. However, if a response is received prior to the timeout period expiring, the method 1000 continues to step 1014.

In one embodiment, if the timeout period has expired without a response being received, the method 1000 may return to step 1010 and the request may be re-transmitted, referred to herein as a retry. The number of retries may be tracked and one or more retries may be attempted before the method 1000 terminates with a determination that the vehicle 810 is in an OFF state.

At step 1014, the device 830 analyzes the value of the parameter for the engine RPM. If the value of the parameter for the engine RPM is greater than zero, indicating the engine is rotating, then the method 1000 terminates with a determination that the vehicle 810 is in an ON state. However, if the value of the parameter for the engine RPM is equal to zero, then the method 1000 proceeds to step 1016, as shown in FIG. 10B. In one embodiment, if the value of the parameter for the engine RPM is equal to the maximum value (e.g., 16,383.75) for the parameter, then the parameter value may be treated as invalid. For example, a parameter value of 0hFFFF can indicate an error with the tachometer and should not be interpreted as a tachometer measurement of 16,383.75 RPM. In such an embodiment, the method 1000 proceeds to step 1016 if the value of the parameter for the engine RPM is either zero or the maximum value for the parameter. In yet another embodiment, the device 830 may require the value of the parameter for the engine RPM to be greater than a threshold value. For example, most vehicles where the engine is running will have a minimum RPM of the idling engine that is at least a few hundred RPM. If the value of the parameter is, say, less than 100 RPM, then the engine is most likely not running and there may be a malfunction of the ECU.

As shown in FIG. 10B, at step 1016, the device 830 determines whether a vehicle speed parameter is supported by the automotive diagnostic port 820. In one embodiment, the device 830 analyzes the PID response to PID code 0h00 received over the CAN bus. The specific PID code for vehicle speed is standardized in SAE J/1979 as 0h0D. Consequently, the MSB of the low nibble of the 2^{nd} most significant byte of the 4 byte parameter value returned in the PID response to PID code 0h00 indicates whether PID code 0h0D is supported by the automotive diagnostic port 820. If the vehicle speed parameter is not supported, then the method 1000 proceeds to step 1024, as shown in FIG. 10C. However, if the vehicle speed parameter is supported by the automotive diagnostic port 820, then the method 1000 proceeds to step 1018.

At step 1018, the device 830 transmits a request over the automotive diagnostic port 820 to retrieve a parameter value for the vehicle speed. In one embodiment, the device 830 transmits a PID request (mode 0h01, PID code 0h0D) over the CAN bus of an OBD-II automotive diagnostic port 820.

At step 1020, the device 830 monitors the automotive diagnostic port 820 for a response to the request to retrieve the parameter value for the vehicle speed. In one embodiment, the device 830 listens for a PID response on the CAN bus that includes a custom mode and PID code that correspond with PID code 0h0D. A PID response to a PID request for PID code 0h0D returns a one byte value for the parameter that represents the speed of the vehicle in one kilometer per hour (km/h) increments, between 0 and 255 km/h. In one embodiment, the device 830 may monitor the bus traffic for a particular period of time as set by a timeout period. When the timeout period expires without receiving a response to the request, the method 1000 terminates with a determination that the vehicle 810 is in an OFF state. However, if a response is received prior to the timeout period expiring, the method 1000 continues to step 1022.

In one embodiment, if the timeout period has expired without a response being received, the method 1000 may return to step 1018 and the request may be re-transmitted, referred to herein as a retry. The number of retries may be tracked and one or more retries may be attempted before the method 1000 terminates with a determination that the vehicle 810 is in an OFF state.

At step 1022, the device 830 analyzes the value of the parameter for the vehicle speed. If the value of the parameter for the vehicle speed is greater than zero, indicating that the vehicle is in motion, then the method 1000 terminates with a determination that the vehicle 810 is in an ON state. However, if the value of the parameter for the vehicle speed is equal to zero, then the method 1000 proceeds to step 1024, as shown in FIG. 10C. In one embodiment, if the value of the parameter for the vehicle speed is equal to the maximum value (e.g., 255) for the parameter, then the parameter value may be treated as invalid. For example, a parameter value of 0hFF can indicate an error with the speedometer and should not be interpreted as a speedometer measurement of 255 km/h. In such an embodiment, the method 1000 proceeds to step 1024 if the value of the parameter for the vehicle speed is either zero or the maximum value for the parameter.

At step 1024, the device 830 determines whether a runtime parameter is supported by the automotive diagnostic port 820. The run time parameter refers to a current elapsed time that the engine has been running. Some vehicles may track this parameter and make it available over the automotive diagnostic port 820. In one embodiment, the device 830 analyzes the PID response to PID code 0h00 received over the CAN bus. The specific PID code for runtime is standardized in SAE J/1979 as 0h1F. Consequently, the penultimate LSB of the low nibble of the least significant byte of the 4 byte parameter value returned in the PID response to PID code 0h00 indicates whether PID code 0h1F is supported by the automotive diagnostic port 820. If the runtime parameter is not supported, then the method 1000 terminates with a determination that the vehicle 810 is in an OFF state. However, if the runtime parameter is supported by the automotive diagnostic port 820, then the method 1000 proceeds to step 1026.

At step 1026, the device 830 transmits a request over the automotive diagnostic port 820 to retrieve a parameter value for the runtime. In one embodiment, the device 830 transmits a PID request (mode 0h01, PID code 0h1F) over the CAN bus of an OBD-II automotive diagnostic port 820.

At step 1028, the device 830 monitors the automotive diagnostic port 820 for a response to the request to retrieve the parameter value for the runtime. In one embodiment, the device 830 listens for a PID response on the CAN bus that includes a custom mode and PID code that correspond with PID code 0h1F. A PID response to a PID request for PID code 0h1F returns a two byte value for the parameter that represents the number of seconds since the engine was started, between 0 and 65,535 seconds (a maximum value of approximately 18 hours and 12 minutes). In one embodiment, the device 830 may monitor the bus traffic for a particular period of time as set by a timeout period. When the timeout period expires without receiving a response to the request, the method 1000 terminates with a determination that the vehicle 810 is in an OFF state. However, if a response is received prior to the timeout period expiring, the method 1000 continues to step 1030.

In one embodiment, if the timeout period has expired without a response being received, the method 1000 may return to step 1026 and the request may be re-transmitted, referred to herein as a retry. The number of retries may be tracked and one or more retries may be attempted before the method 1000 terminates with a determination that the vehicle 810 is in an OFF state.

At step 1030, the device 830 analyzes the value of the parameter for the runtime. If the value of the parameter for the runtime is greater than zero, indicating that the engine was started some non-zero time prior to the response being sent over the bus, then the method 1000 terminates with a determination that the vehicle 810 is in an ON state. However, if the value of the parameter for the runtime is equal to zero, then the method 1000 terminates with a determination that the vehicle 810 is in an OFF state.

It will be appreciated that the method 1000 describes monitoring a voltage waveform of the vehicle's battery source, accelerometer sensor data, and/or bus activity to sense, automatically, when a vehicle transitions from an OFF state to an ON state. These triggers then cause the device 830 to actively attempt to verify the state of the vehicle by querying the vehicle systems over the automotive diagnostic port 820. Being able to sense the vehicle 810 was started automatically enables the device to trigger one or more applications configured to utilize vehicle data when the engine of the vehicle 810 is running and/or the vehicle 810 is in motion.

FIG. 10D illustrates a system 1050 for detecting an ignition check event, in accordance with one embodiment. As shown in FIG. 10D, the system 1050 includes the device 830 coupled to a battery 1052 included in the vehicle 810 via the automotive diagnostic port 820. The positive and negative battery voltage are coupled to pins of the automotive diagnostic port 820 and routed to power supply pins on the ASIC 100 included in the device 830. In one embodiment, the power supply pins on the ASIC 100 may also be routed to the ADC 122 via the crossbar 120 in order to measure a voltage level of the power supply pins of the automotive diagnostic port 820. The device 830 may also include one or more accelerometers 1054 coupled to the device via general purpose I/O 144 on the ASIC 100. Although not explicitly shown, the other pins of the automotive diagnostic port 820 may be coupled to AGPIO 200 in the I/O port 110 on the ASIC 100.

Signals from the accelerometers 1054 received via GPIO 144 and/or the signals from the battery 1052 received via the power pins may be coupled to logic implemented in the ASIC 100 and/or a processor core coupled to the ASIC 100 via processor bus 180. The logic is configured to trigger an ignition check event in response to conditions detected by the signals from the accelerometers 1054 and/or the battery 1052.

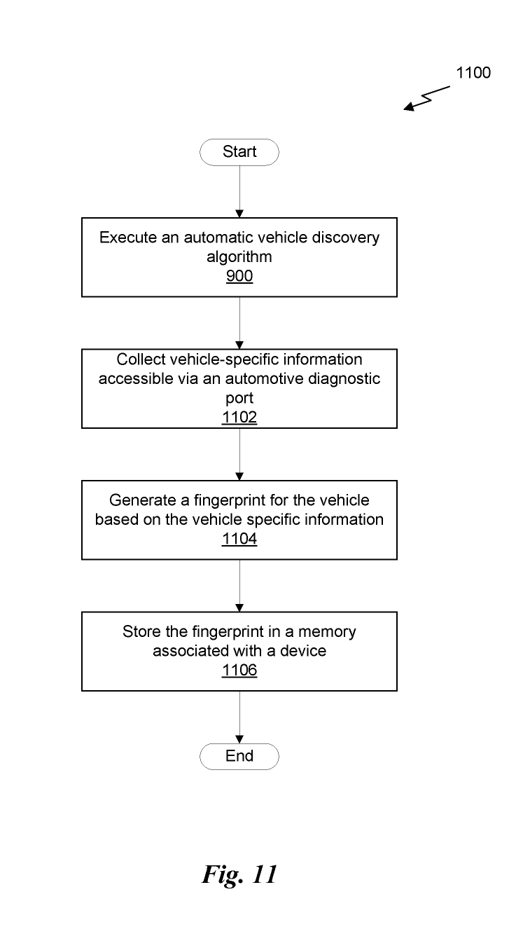

FIG. 11 illustrates a flowchart of a method 1100 for generating a fingerprint of a vehicle 810, in accordance with one embodiment. The method 1100 may be performed by hardware, software, or a combination of hardware and software. In one embodiment, the method 1100 may be implemented by some combination of the device 830, the mobile device 840, and/or the server 850. The method 1100 may be initiated by executing a method 900 for executing an automatic vehicle discovery algorithm, as shown above in FIG. 9.

The method 1100 continues at step 1102, by collecting vehicle-specific information accessible via the automotive diagnostic port 820. Vehicle-specific information may include a signal map of the automotive diagnostic port 820 corresponding to one or more states of the ignition switch of the vehicle 810; a VIN number of the vehicle 810; the addresses of one or more electronic systems coupled to a particular communications bus coupled to the automotive diagnostic port 820 of the vehicle 810; a fuel type of the vehicle 810; an ECU name for the vehicle 810; a bit map of PID codes supported by the vehicle 810; and/or any particular set of data that can be correlated to a vehicle 810 and retrieved via the automotive diagnostic port 820.

At step 1104, a fingerprint for the vehicle 810 is generated based on the vehicle-specific information. In one embodiment, the fingerprint is a data structure that encodes the vehicle-specific information for one or more fields. For example, the fingerprint may be a key value data store, each key corresponding to a different field that identifies a particular piece of vehicle-specific information. In another embodiment, the vehicle-specific information is formatted into a data structure and then hashed using a hash function to produce a hash value corresponding to the vehicle-specific information. The fingerprint then stores the hash value rather than the larger vehicle-specific information.

At step 1106, the fingerprint is stored in a memory associated with the device 830. In one embodiment, the fingerprint is stored in a non-volatile memory (e.g., flash memory) included in or accessible by the device 830. In another embodiment, the fingerprint is transmitted to the mobile device 840 and stored in the memory of the mobile device 840. The device 830 may then query the mobile device 840 for the fingerprint when the device 830 is activated or brought out of standby mode.

The fingerprint can be used to determine if the device 830 is still connected to the same vehicle at later points in time. In one embodiment, the vehicle-specific information stored in the fingerprint can later be compared against new vehicle-specific information collected from the vehicle at later points in time. In another embodiment, the hash value stored in the fingerprint can later be compared against new hash values generated via the hash function after collecting vehicle-specific information from the vehicle at later points in time. The fingerprint enables the automatic vehicle discovery algorithm to skip steps in particular starting sequences.

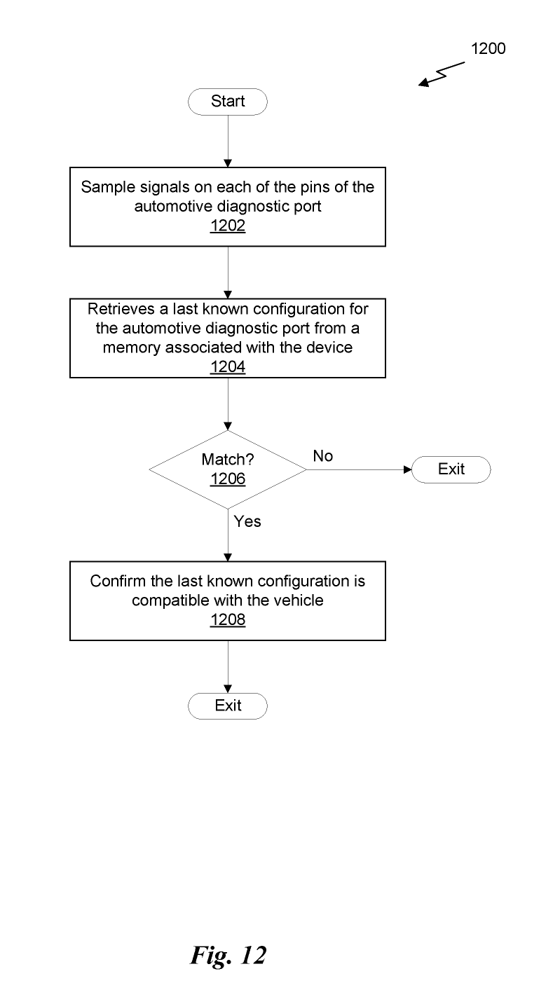

FIG. 12 illustrates a flowchart of a method 1200 for executing the automatic vehicle discovery algorithm in a cold start mode, in accordance with one embodiment. The method 1200 may be performed by hardware, software, or a combination of hardware and software. In one embodiment, the method 1200 may be implemented by some combination of the device 830, the mobile device 840, and/or the server 850.

The cold start mode refers to a start-up mode where a device 830 is connected to an automotive diagnostic port 820 after having been connected to at least one vehicle 810 in the past. Once method 900 has been performed at least once for a vehicle 810, and a fingerprint for the vehicle 810 has been stored in a memory associated with the device 830, then the automatic vehicle discovery algorithm may be performed more quickly by assuming that it is very likely that the device 830 is connected to the same vehicle 810 when retrieving the list of configurations (i.e., the list of configurations may only include a single configuration that was equal to the configuration of the automotive diagnostic port most recently connected to the device). However, steps need to be taken to ensure that the device 830 has not been moved to a new vehicle 810 before the device 830 is placed into a normal operating mode.

At step 1202, a signal is sampled on each pin of a plurality of pins of the automotive diagnostic port 820. Step 1202 may be similar to step 902 of method 900. A signal map is generated that correlates each pin of the plurality of pins of the automotive diagnostic port 820 to a voltage and/or activity level.

At step 1204, a last known configuration of the automotive diagnostic port 820 is retrieved from a memory associated with the device 830. It will be appreciated that instead of retrieving a list of all potential configurations of the automotive diagnostic port 820 and determining which configuration(s) in the list match the signal map, as described in method 900, the automatic vehicle discovery algorithm may proceed using an alternate path where the last known configuration of the automotive diagnostic port 820 is assumed to be the same as the current configuration of the automotive diagnostic port 820 connected to the device 830. Most users switch vehicles very infrequently and, therefore, the device 830 is very likely to be connected to the same vehicle repeatedly. Therefore, time may be saved when performing the vehicle discovery algorithm by first attempting to match the signal map to the last known configuration of the automotive diagnostic port 820.

At step 1206, the device 830 determines if the last known configuration of the automotive diagnostic port 820 matches the signal map. If the last known configuration of the automotive diagnostic port 820 does not match the signal map, then the assumption is that the device 830 may have been connected to a new vehicle and method 1200 is terminated and the full vehicle discovery algorithm as illustrated in method 900 may be executed to determine a configuration of the automotive diagnostic port 820 connected to the device 830. However, if the last known configuration of the automotive diagnostic port 820 matches the signal map, then the method proceeds to step 1208, where the device 830 confirms that the last known configuration is compatible with the vehicle 810. It will be appreciated that a match between the signal map and the last known configuration does not confirm that the vehicle 810 connected to the device 830 currently is the same vehicle that was previously connected to the device 830. A match simply indicates that the tested pins of the automotive diagnostic port 820 have signals that are similar to signals expected given the last known configuration of the automotive diagnostic port 820 and, therefore, it is highly probable that specific pins are used for a given communication protocol, which enables further checks to be performed to confirm the configuration of the automotive diagnostic port 820.

In one embodiment, the device 830 collects vehicle-specific information via the automotive diagnostic port 820 in order to compare the vehicle-specific information to a fingerprint associated with the last known configuration. For example, the device 830 may retrieve a VIN of the vehicle using a PID request broadcast over a CAN bus coupled to the automotive diagnostic port 820, and compare the VIN included in a PID response to a VIN stored in the fingerprint in order to confirm that the last known configuration is compatible with the vehicle 810.

If the last known configuration is confirmed, then the device 830 may be placed in a normal operating mode using the last known configuration as the current configuration of the automotive diagnostic port 820. If the last known configuration is not confirmed, then the method 1200 may terminate and the full automatic vehicle discovery algorithm may be executed according to method 900. It will be appreciated that method 1200 is similar to method 900 except that method 1200 is typically quicker as there is only one configuration that is likely to match the signal map generated in response to sampling the signals of the automotive diagnostic port 820. In many typical use cases where a device is connected to the same vehicle repeatedly, this can speed up the time between turning on the device 830 and putting the device 830 into a normal operating mode when compared to a completely new startup mode where the device 830 has never been connected to a particular vehicle before.

In an alternative embodiment, a device 830 may store a plurality of known configurations corresponding to a plurality of vehicles 810 that have previously been connected to the device 830. Step 1206 then matches the signal map to the plurality of known configurations in an attempt to discover the vehicle currently connected to the device 830, discarding any configurations that do not match the signal map, and attempting to confirm any configuration that matches the signal map using vehicle-specific information collected via the automotive diagnostic port 820. Thus, if a user connects the device 830 to a small number of personal vehicles 810, the device 830 may quickly discover which of the vehicles 810 it has been connected to using a list of configurations corresponding to vehicles 810 the device 830 has been connected to in the past.

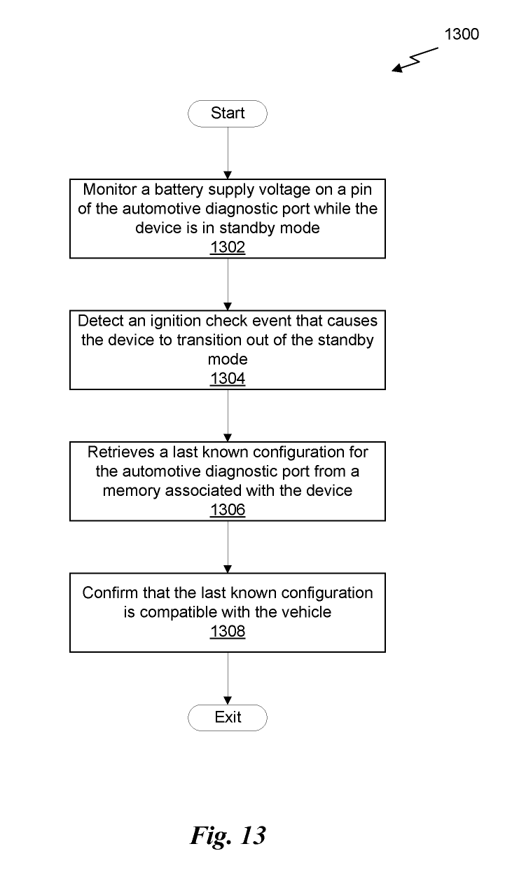

FIG. 13 illustrates a flowchart of a method 1300 for executing the automatic vehicle discovery algorithm in a hot start mode, in accordance with one embodiment. The method 1300 may be performed by hardware, software, or a combination of hardware and software. In one embodiment, the method 1300 may be implemented by some combination of the device 830, the mobile device 840, and/or the server 850.

A hot start mode may differ from a cold start mode and the vehicle discovery process may be sped up even more. The hot start mode is defined as bringing the device 830 out of a standby mode to a normal operating mode when the device 830 has not been disconnected from a battery supply voltage from the automotive diagnostic port 820. Consequently, the device 830 can read the last known configuration from a memory and then attempt to confirm that the vehicle 810 is compatible with the last known configuration without generating a signal map of the pins of the automotive diagnostic port 820.

At step 1302, the device 830 monitors a battery supply voltage on a pin of the automotive diagnostic port while the device is in a standby mode. In one embodiment, the device 830 can only startup in the hot start mode when the battery supply voltage has not been disconnected while the device 830 was in standby mode. At step 1304, the device 830 detects an ignition check event that causes the device to transition out of standby mode. As described above, the ignition check event may be triggered by monitoring a battery supply voltage waveform on a pin of the automotive diagnostic port or detecting motion of the vehicle based on feedback from one or more sensors (e.g., accelerometers).

At step 1306, the device 830 retrieves a last known configuration of the automotive diagnostic port 820 from a memory associated with the device 830. At step 1308, the device 830 confirms that the last known configuration is compatible with the vehicle 810 connected to the device 830. The device 830 may immediately request vehicle-specific information over the automotive diagnostic port 820 based on the last known configuration in order to confirm that the last known configuration is compatible with the vehicle 810 connected to the device 830. As long as the last known configuration is compatible with the vehicle 810 connected to the device 830, then the device 830 may be placed in a normal operating mode. Otherwise, the method 1300 may terminate and the full automatic vehicle discovery algorithm may be executed according to method 900.

It will be appreciated that the vehicle discovery algorithm disclosed above has been described with reference to the hardware of FIGS. 1-7. However, nothing in this description should be construed as limiting the techniques described therein to implementations requiring said hardware. For example, the functionality of ASIC 100 could be performed by other hardware components, digital signal processors, and/or systems-on-chip, utilizing software, hardware, or a combination of hardware and software to implement the functionality required therein. The ASIC 100 and related hardware/software are simply one exemplary embodiment of a system configured to perform the methods of FIGS. 9A-9B, 10A-10C, and 11-13.

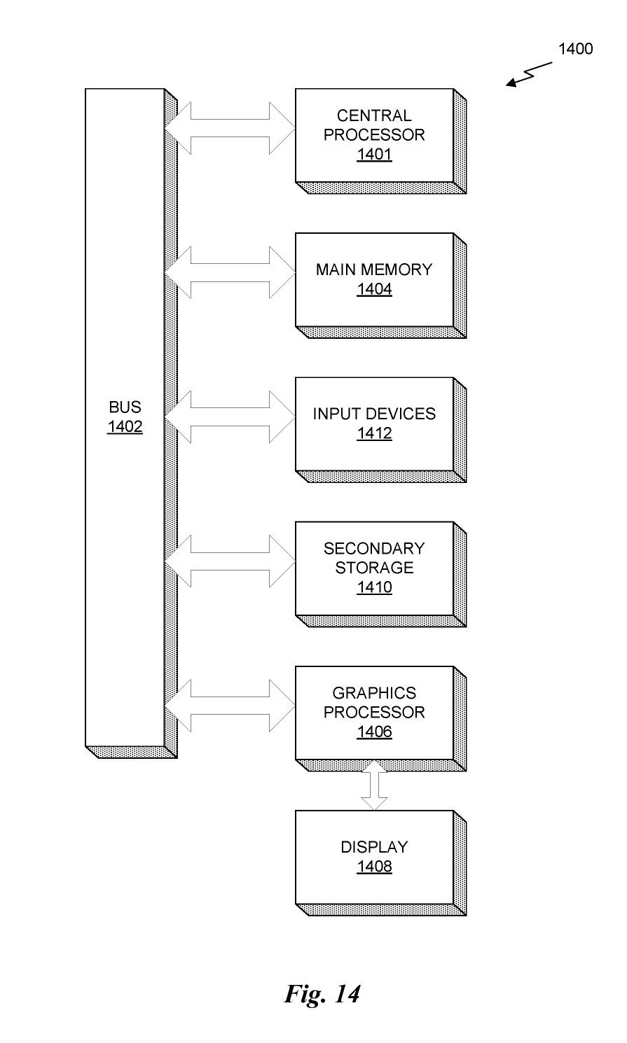

FIG. 14 illustrates an exemplary system 1400 in which the various architecture and/or functionality of the various previous embodiments may be implemented. For example, the mobile device 840 and/or server 850 may be implemented as the system 1400. As shown, a system 1400 is provided including at least one central processor 1401 that is connected to a communication bus 1402. The communication bus 1402 may be implemented using any suitable protocol, such as PCI (Peripheral Component Interconnect), PCI-Express, AGP (Accelerated Graphics Port), HyperTransport, or any other bus or point-to-point communication protocol(s). The system 1400 also includes a main memory 1404. Control logic (software) and data are stored in the main memory 1404 which may take the form of random access memory (RAM).

The system 1400 also includes input devices 1412, a graphics processor 1406, and a display 1408, i.e. a conventional CRT (cathode ray tube), LCD (liquid crystal display), LED (light emitting diode), plasma display or the like. User input may be received from the input devices 1412, e.g., keyboard, mouse, touchpad, microphone, and the like. In one embodiment, the graphics processor 1406 may include a plurality of shader modules, a rasterization module, etc. Each of the foregoing modules may even be situated on a single semiconductor platform to form a graphics processing unit (GPU).

In the present description, a single semiconductor platform may refer to a sole unitary semiconductor-based integrated circuit or chip. It should be noted that the term single semiconductor platform may also refer to multi-chip modules with increased connectivity which simulate on-chip operation, and make substantial improvements over utilizing a conventional central processing unit (CPU) and bus implementation. Of course, the various modules may also be situated separately or in various combinations of semiconductor platforms per the desires of the user.

The system 1400 may also include a secondary storage 1410. The secondary storage 1410 includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 1404 and/or the secondary storage 1410. Such computer programs, when executed, enable the system 1400 to perform various functions. The memory 1404, the storage 1410, and/or any other storage are possible examples of computer-readable media.

In one embodiment, the architecture and/or functionality of the various previous figures may be implemented in the context of the central processor 1401, the graphics processor 1406, an integrated circuit (not shown) that is capable of at least a portion of the capabilities of both the central processor 1401 and the graphics processor 1406, a chipset (i.e., a group of integrated circuits designed to work and sold as a unit for performing related functions, etc.), and/or any other integrated circuit for that matter.

Still yet, the architecture and/or functionality of the various previous figures may be implemented in the context of a general computer system, a circuit board system, a game console system dedicated for entertainment purposes, an application-specific system, and/or any other desired system. For example, the system 1400 may take the form of a desktop computer, laptop computer, server, workstation, game consoles, embedded system, and/or any other type of logic. Still yet, the system 1400 may take the form of various other devices including, but not limited to a personal digital assistant (PDA) device, a mobile phone device, a television, etc.

Further, while not shown, the system 1400 may be coupled to a network (e.g., a telecommunications network, local area network (LAN), wireless network, wide area network (WAN) such as the Internet, peer-to-peer network, cable network, or the like) for communication purposes.

It is noted that the techniques described herein, in an aspect, are embodied in executable instructions stored in a computer readable medium for use by or in connection with an instruction execution machine, apparatus, or device, such as a computer-based or processor-containing machine, apparatus, or device. It will be appreciated by those skilled in the art that for some embodiments, other types of computer readable media are included which may store data that is accessible by a computer, such as magnetic cassettes, flash memory cards, digital video disks, Bernoulli cartridges, random access memory (RAM), read-only memory (ROM), and the like.

As used here, a “computer-readable medium” includes one or more of any suitable media for storing the executable instructions of a computer program such that the instruction execution machine, system, apparatus, or device may read (or fetch) the instructions from the computer readable medium and execute the instructions for carrying out the described methods. Suitable storage formats include one or more of an electronic, magnetic, optical, and electromagnetic format. A non-exhaustive list of conventional exemplary computer readable medium includes: a portable computer diskette; a RAM; a ROM; an erasable programmable read only memory (EPROM or flash memory); optical storage devices, including a portable compact disc (CD), a portable digital video disc (DVD), a high definition DVD (HD-DVD™), a BLU-RAY disc; and the like.

It should be understood that the arrangement of components illustrated in the Figures described are exemplary and that other arrangements are possible. It should also be understood that the various system components (and means) defined by the claims, described below, and illustrated in the various block diagrams represent logical components in some systems configured according to the subject matter disclosed herein.

For example, one or more of these system components (and means) may be realized, in whole or in part, by at least some of the components illustrated in the arrangements illustrated in the described Figures. In addition, while at least one of these components are implemented at least partially as an electronic hardware component, and therefore constitutes a machine, the other components may be implemented in software that when included in an execution environment constitutes a machine, hardware, or a combination of software and hardware.

More particularly, at least one component defined by the claims is implemented at least partially as an electronic hardware component, such as an instruction execution machine (e.g., a processor-based or processor-containing machine) and/or as specialized circuits or circuitry (e.g., discreet logic gates interconnected to perform a specialized function). Other components may be implemented in software, hardware, or a combination of software and hardware. Moreover, some or all of these other components may be combined, some may be omitted altogether, and additional components may be added while still achieving the functionality described herein. Thus, the subject matter described herein may be embodied in many different variations, and all such variations are contemplated to be within the scope of what is claimed.

In the description above, the subject matter is described with reference to acts and symbolic representations of operations that are performed by one or more devices, unless indicated otherwise. As such, it will be understood that such acts and operations, which are at times referred to as being computer-executed, include the manipulation by the processor of data in a structured form. This manipulation transforms the data or maintains it at locations in the memory system of the computer, which reconfigures or otherwise alters the operation of the device in a manner well understood by those skilled in the art. The data is maintained at physical locations of the memory as data structures that have particular properties defined by the format of the data. However, while the subject matter is being described in the foregoing context, it is not meant to be limiting as those of skill in the art will appreciate that various acts and operations described hereinafter may also be implemented in hardware.

To facilitate an understanding of the subject matter described herein, many aspects are described in terms of sequences of actions. At least one of these aspects defined by the claims is performed by an electronic hardware component. For example, it will be recognized that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar referents in the context of describing the subject matter (particularly in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. Furthermore, the foregoing description is for the purpose of illustration only, and not for the purpose of limitation, as the scope of protection sought is defined by the claims as set forth hereinafter together with any equivalents thereof entitled to. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

The embodiments described herein include the one or more modes known to the inventor for carrying out the claimed subject matter. It is to be appreciated that variations of those embodiments will become apparent to those of ordinary skill in the art upon reading the foregoing description. The inventor expects skilled artisans to employ such variations as appropriate, and the inventor intends for the claimed subject matter to be practiced otherwise than as specifically described herein. Accordingly, this claimed subject matter includes all modifications and equivalents of the subject matter recited in the claims appended hereto as permitted by applicable law. Moreover, any combination of the above-described elements in all possible variations thereof is encompassed unless otherwise indicated herein or otherwise clearly contradicted by context.

What is claimed is:

1. A method, comprising:
sampling a signal on each pin of a plurality of pins of the automotive diagnostic port to generate a signal map corresponding with the automotive diagnostic port;
selecting a configuration from a list of configurations for the automotive diagnostic port based on the signal map; and
establishing communication with the vehicle via the automotive diagnostic port based on the selected configuration.

2. The method of claim 1, wherein selecting the configuration from the list of configurations comprises:
receiving the list of configurations;
selecting a subset of configurations as potential configurations that match the signal map;
selecting a particular configuration from the subset of configurations;
attempting to establish communication with the vehicle using a communications protocol via one or more pins of the automotive diagnostic port, wherein the particular configuration identifies the one or more pins of the automotive diagnostic port that implement the communications protocol; and
if the attempt to establish communications with the vehicle is successful, then selecting the particular configuration as a selected configuration for the vehicle, or
if the attempt to establish communications with the vehicle fails, then removing the particular configuration from the subset of configurations and repeating the steps of selecting a different configuration from the subset of configurations and attempting to establish communications with the vehicle based on the different configuration.

3. The method of claim 2, wherein receiving the list of configurations comprises:
transmitting a request for the list of configurations from the device to a server; and
receiving a response to the request from the server that includes the list of configurations.

4. The method of claim 2, wherein the device is coupled to a mobile device configured to establish an Internet connection, and wherein an application executed by the mobile device is configured to:
transmit a request for the list of configurations to a server; and
store the list of configurations in a memory associated with the mobile device accessible by the device.

5. The method of claim 4, further comprising prompting, via a display included in the mobile device, a user to plug the device into the automotive diagnostic port of the vehicle after placing the vehicle into an OFF state prior to sampling the signal on each pin of the plurality of pins of the automotive diagnostic port.

6. The method of claim 1, further comprising requesting a Vehicle Identification Number (VIN) via the automotive diagnostic port and storing the VIN in a memory associated with the device.

7. The method of claim 1, further comprising:
collecting vehicle-specific information accessible via the automotive diagnostic port;
generating a fingerprint for the vehicle based on the vehicle-specific information; and
storing the fingerprint in a memory associated with the device.

8. The method of claim 1, wherein selecting the configuration from the list of configurations based on the signal map comprises:
retrieving a last known configuration of the automotive diagnostic port from a memory associated with the device;
determining that the last known configuration matches the signal map; and
confirming that the last known configuration is compatible with the vehicle.

9. The method of claim 1, further comprising:
monitoring a battery supply voltage on a pin of the automotive diagnostic port while the device is in a standby mode;
detecting an ignition check event that causes the device to transition out of the standby mode;
retrieving a last known configuration for the automotive diagnostic port from a memory associated with the device; and
confirming that the last known configuration is compatible with the vehicle.

10. The method of claim 1, further comprising:
detecting an ignition check event; and
determining the state of a vehicle based on information retrieved via the automotive diagnostic port.

11. The method of claim 10, wherein detecting the ignition check event comprises at least one of:
monitoring a battery supply voltage waveform on a pin of the automotive diagnostic port; and
detecting motion of the vehicle based on feedback from one or more sensors.

12. A system, comprising:
a device connected to an automotive diagnostic port for a vehicle, the device configured to:
sample a signal on each pin of a plurality of pins of the automotive diagnostic port to generate a signal map corresponding with the automotive diagnostic port,
select a configuration from a list of configurations based on the signal map, and
establish communications with the vehicle via the automotive diagnostic port based on the selected configuration.

13. The system of claim 12, wherein the device is configured to select the configuration from the list of configurations by:
receiving the list of configurations;
selecting a subset of configurations as potential configurations that match the signal map;
selecting a particular configuration from the subset of configurations;
attempting to establish communication with the vehicle using a communications protocol via one or more pins of the automotive diagnostic port, wherein the particular configuration identifies the one or more pins of the automotive diagnostic port that implement the communications protocol; and
if the attempt to establish communications with the vehicle is successful, then selecting the particular configuration as a selected configuration for the vehicle, or
if the attempt to establish communications with the vehicle fails, then removing the particular configuration from the subset of configurations and repeating the steps of selecting a different configuration from the subset of configurations and attempting to establish communications with the vehicle based on the different configuration.

14. The system of claim 13, the system further comprising a server, and wherein receiving the list of configurations for the automotive diagnostic port comprises:
transmitting a request for the list of potential configurations from the device to the server; and
receiving a response to the request from the server that includes the list of potential configurations.

15. The system of claim 14, further comprising a mobile device coupled to the device and configured to establish an Internet connection, and wherein an application executed by the mobile device is configured to:
transmit a request for the list of configurations to a server via the Internet connection; and
store the list of configurations in a memory associated with the mobile device accessible by the device.

16. The system of claim 12, wherein the device includes an application specific integrated circuit (ASIC) that includes a plurality of automotive general purpose input/outputs (AGPIOs) for sampling the signal on each pin of the plurality of pins of the automotive diagnostic port.

17. The system of claim 12, the device further configured to request a Vehicle Identification Number (VIN) via the automotive diagnostic port and store the VIN in a memory associated with the device.

18. The system of claim 12, the device further configured to:
collect vehicle-specific information accessible via the automotive diagnostic port;
generate a fingerprint for the vehicle based on the vehicle-specific information; and
store the fingerprint in a memory associated with the device

19. The system of claim 12, wherein selecting the configuration from the list of configurations based on the signal map comprises:
retrieving a last known configuration of the automotive diagnostic port from a memory associated with the device;
determining that the last known configuration matches the signal map; and
confirming that the last known configuration is compatible with the vehicle.

20. The system of claim 12, the device further configured to:
monitor a battery supply voltage on a pin of the automotive diagnostic port while the device is in a standby mode;
detect an ignition check event that causes the device to transition out of the standby mode;
retrieve a last known configuration for the automotive diagnostic port from a memory associated with the device; and
confirm that the last known configuration is compatible with the vehicle.
